(19) United States
(12) Patent Application Publication
(10) Pub. No.: US 2026/0107523 A1
(43) Pub. Date: Apr. 16, 2026

(54) SILICON CARBIDE SEMICONDUCTOR DEVICE AND METHOD OF MANUFACTURING SILICON CARBIDE SEMICONDUCTOR DEVICE

(71) Applicant: FUJI ELECTRIC CO., LTD., Kawasaki-shi (JP)

(72) Inventors: Takeshi TAWARA, Tsukuba-city (JP); Kensuke TAKENAKA, Tsukuba-city (JP); Shinsuke HARADA, Tsukuba-shi (JP)

(73) Assignee: FUJI ELECTRIC CO., LTD., Kawasaki-shi (JP)

(21) Appl. No.: 19/343,446

(22) Filed: Sep. 29, 2025

(30) Foreign Application Priority Data
Oct. 11, 2024 (JP) 2024-178644

(51) Int. Cl. H10D 62/10; H10D 30/01; H10D 30/66; H10D 62/00; H10D 62/832

(52) U.S. Cl. CPC H10D 62/111; H10D 30/0297; H10D 30/668; H10D 62/054; H10D 62/8325

(57) ABSTRACT

A semiconductor device, including: a semiconductor substrate made of silicon carbide; a parallel pn layer having a plurality of first-conductivity-type regions and a plurality of second-conductivity-type regions repeatedly alternating each other; a first semiconductor region between a first main surface of the semiconductor substrate and the parallel pn layer; a plurality of second semiconductor regions between the first main surface and the first semiconductor region; a plurality of trenches penetrating through the second semiconductor regions, respectively, and through the first semiconductor region, and reaching the parallel pn layer; a plurality of gate electrodes provided in the plurality of trenches via a plurality of gate insulating films; a first electrode electrically connected to the first semiconductor region and the second semiconductor regions; and a second electrode provided at a second main surface of the semiconductor substrate. The first semiconductor region intersects with the second-conductivity-type regions at a plurality of intersecting portions.

### CROSS REFERENCE TO RELATED APPLICATIONS

This application is based upon and claims the benefit of priority of the prior Japanese Patent Application No. 2024-178644, filed on Oct. 11, 2024, the entire contents of which are incorporated herein by reference.

### BACKGROUND OF THE INVENTION

### 1. Field of the Invention

Embodiments of the invention relate to a silicon carbide semiconductor device and a method of manufacturing a silicon carbide semiconductor device.

### 2. Description of the Related Art

In a known conventional metal-oxide-semiconductor field effect transistor having insulated gates with a metal-oxide-semiconductor three-layer structure (MOSFET) and superjunction (SJ) structure in which, in a drift layer, n-type regions and p-type regions are disposed repeatedly alternating with each other in a direction parallel to a main surface of a semiconductor substrate, the SJ structure is formed using a multistage epitaxy method (for example, refer to Japanese Laid-Open Patent Publication No. 2015-216182). International Publication No. WO 2020/110514 also described a similar technique.

### SUMMARY OF THE INVENTION

According to an embodiment of the disclosure, a silicon carbide semiconductor device, includes: a semiconductor substrate made of silicon carbide, the semiconductor substrate having a first main surface and a second main surface opposite to each other; a parallel pn layer provided in the semiconductor substrate, the parallel pn layer having a plurality of first-conductivity-type regions of a first conductivity type and a plurality of second-conductivity-type regions of a second conductivity type, repeatedly alternating each other in a first direction parallel to the first main surface of the semiconductor substrate; a first semiconductor region of the second conductivity type, provided in the semiconductor substrate between the first main surface and the parallel pn layer; a plurality of second semiconductor regions of the first conductivity type, each thereof selectively provided in the semiconductor substrate between the first main surface and the first semiconductor region; a plurality of trenches penetrating through the plurality of second semiconductor regions, respectively, and through the first semiconductor region, in a depth direction of the silicon carbide semiconductor device and reaching the parallel pn layer; a plurality of gate insulating films provided in the plurality of trenches; a plurality of gate electrodes provided in the plurality of trenches via the plurality of gate insulating films; a first electrode electrically connected to the first semiconductor region and the plurality of second semiconductor regions; and a second electrode provided at the second main surface of the semiconductor substrate. Each of the plurality of first-conductivity-type regions and the plurality of second-conductivity-type regions extends linearly in a second direction parallel to the first main surface and orthogonal to the first direction. Each of the plurality of trenches extends linearly parallel to the first main surface, and has at least a portion thereof facing one of the plurality of second-conductivity-type regions in the depth direction. The first semiconductor region extends along sidewalls of the plurality of trenches, and the first semiconductor region intersects with the plurality of second-conductivity-type regions at a plurality of intersecting portions.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a perspective view depicting a structure of a silicon carbide semiconductor device according to a first embodiment.

FIG. 2 is a perspective view depicting the structure of the silicon carbide semiconductor device according to the first embodiment.

FIG. 3 is a perspective view depicting the structure of the silicon carbide semiconductor device according to the first embodiment.

FIG. 4 is a perspective view depicting a state of the silicon carbide semiconductor device according to the first embodiment during manufacture.

FIG. 5 is a perspective view depicting a state of the silicon carbide semiconductor device according to the first embodiment during manufacture.

FIG. 6 is a perspective view depicting a state of the silicon carbide semiconductor device according to the first embodiment during manufacture.

FIG. 7 is a perspective view depicting a state of the silicon carbide semiconductor device according to the first embodiment during manufacture.

FIG. 8 is a perspective view depicting a state of the silicon carbide semiconductor device according to the first embodiment during manufacture.

FIG. 9 is a perspective view depicting a state of the silicon carbide semiconductor device according to the first embodiment during manufacture.

FIG. 10 is a perspective view depicting a state of the silicon carbide semiconductor device according to the first embodiment during manufacture.

FIG. 11 is a perspective view depicting a state of the silicon carbide semiconductor device according to the first embodiment during manufacture.

FIG. 12 is a perspective view depicting a state of the silicon carbide semiconductor device according to the first embodiment during manufacture.

FIG. 13 is a perspective view depicting a state of the silicon carbide semiconductor device according to the first embodiment during manufacture.

FIG. 14 is a perspective view depicting a state of the silicon carbide semiconductor device according to the first embodiment during manufacture.

FIG. 15 is a perspective view depicting the structure of the silicon carbide semiconductor device according to a second embodiment.

FIG. 16 is a cross-sectional view depicting the structure of the silicon carbide semiconductor device according to a third embodiment.

FIG. 17 is a diagram schematically depicting results of simulation of distribution of an implanted p-type dopant that passes through the resist film of the silicon carbide epitaxial layer.

FIG. 18A is a characteristics diagram of results of simulation of a dopant concentration profile of an epitaxial layer of a first example, in a depth direction.

FIG. 18B is a cross-sectional view of a structure of the first example.

### DETAILED DESCRIPTION OF THE INVENTION

First, problems associated with the conventional techniques are discussed. As described in International Publication No. WO 2020/110514, in the formation of the SJ structure using a multistage epitaxy method, stacking of n-type epitaxial layers (epitaxial growth), formation of an ion implantation mask, ion-implantation of a p-type dopant, and removal of the ion implantation mask are repeatedly performed in the sequence stated and under the same conditions. In an instance in which silicon carbide (SiC) is a semiconductor material, dopants in the SiC do not diffuse easily and typically, the number of stages (number of stacked layers) of the n-type epitaxial layer is increased while the thickness of the layer at each stage is thinner. Thus, the number of times that the described processes are repeated in the multistage epitaxy method increases, manufacturing lead-time increases, and the manufacturing cost increases.

An outline of an embodiment of the present disclosure is described. (1) A silicon carbide semiconductor device according to an aspect of the present disclosure is as follows. A parallel pn layer is provided in a semiconductor substrate made of silicon carbide. The parallel pn layer is formed by a plurality of first-conductivity-type regions and a plurality of second-conductivity-type regions disposed repeatedly alternating with each other in a first direction orthogonal to a first main surface of the semiconductor substrate. Between the first main surface and the parallel pn layer, a first semiconductor region of a second conductivity type is provided. Between the first main surface and the first semiconductor region, a plurality of second semiconductor regions of the first conductivity type, is selectively provided. Each of a plurality of trenches penetrate through the plurality of second semiconductor regions and the first semiconductor region in a depth direction and reach the parallel pn layer.

In the plurality of trenches, a plurality of gate electrodes is provided via a plurality of gate insulating films. A first electrode is electrically connected to the first semiconductor region and the plurality of second semiconductor regions. A second electrode is provided at a second main surface of the semiconductor substrate. The plurality of first-conductivity-type regions and the plurality of second-conductivity-type regions extend linearly in a second direction that is parallel to the first main surface and orthogonal to the first direction. Each of the plurality of trenches extends linearly parallel to the first main surface and at least a portion thereof faces a corresponding one of the plurality of second-conductivity-type regions in the depth direction. The first semiconductor region extends along sidewalls of the plurality of trenches. The first semiconductor region penetrates through the plurality of second-conductivity-type regions.

According to the disclosure above, the parallel pn layer can be formed without using a multistage epitaxy method and thus, manufacturing processes are simplified, and costs can be reduced.

(2) Further, in the semiconductor device according to the disclosure, in (1) above, a dopant concentration of the plurality of second-conductivity-type regions, at portions thereof penetrating through the first semiconductor region may be lower than a dopant concentration of the first semiconductor region.

According to the disclosure above, on-resistance can be reduced.

(3) Further, in the semiconductor device according to the disclosure, in (1) or (2) above, a depth of the plurality of second-conductivity-type regions may be in a range of 0.8 μm to 3.2 μm.

According to the disclosure above, by a single session of ion implantation by a high acceleration energy, the depth of the plurality of second-conductivity-type regions can be suitably set.

(4) Further, a silicon carbide semiconductor device according to one aspect of the present disclosure is as follows. A parallel pn layer is provided in a semiconductor substrate made of silicon carbide. The parallel pn layer is formed by a plurality of first-conductivity-type regions and a plurality of second-conductivity-type regions disposed repeatedly alternating each other in a first direction parallel to a first main surface of semiconductor substrate. Between the first main surface and the parallel pn layer, a first semiconductor region of a second conductivity type is provided. Between the first main surface and the first semiconductor region, a plurality of second semiconductor regions of the first conductivity type is selectively provided. Each of a plurality of trenches penetrates through the plurality of second semiconductor regions and the first semiconductor region in the depth direction and reaches the parallel pn layer. In the plurality of trenches, a plurality of gate electrodes is provided via a plurality of gate insulating films. A first electrode is electrically connected to the first semiconductor region and the plurality of second semiconductor regions. A second electrode is provided at a second main surface of the semiconductor substrate.

The plurality of first-conductivity-type regions and the plurality of second-conductivity-type regions extend linearly in a second direction that is parallel to the first main surface and orthogonal to the first direction. The plurality of trenches face the plurality of second-conductivity-type regions in the depth direction and extend linearly in the second direction. Each of the plurality of second semiconductor regions is provided apart from others of the plurality of second semiconductor regions in the second direction, along sidewalls of the plurality of trenches. A plurality of third semiconductor regions of the first conductivity type, is provided in the plurality of second-conductivity-type regions, at positions closer to the second main surface than is a first semiconductor region and facing the plurality of second semiconductor regions in the depth direction. Each of the plurality of third semiconductor regions has a first end in the first direction in contact with a corresponding one of the plurality of gate insulating films at the sidewalls of a corresponding one of the plurality of trenches and a second end in the first direction in contact with a corresponding one of the plurality of first-conductivity-type regions.

According to the disclosure above, the parallel pn layer can be formed without using a multistage epitaxy method and thus, manufacturing processes are simplified, and costs can be reduced. Further, the channel area can be increased, and channel characteristics are improved.

(5) Further, in the semiconductor device according to the disclosure, in (4) above, each of a plurality of high-concentration regions of the second conductivity type, is selectively provided between a bottom of a corresponding one of the plurality of trenches and a corresponding one of the plurality of second-conductivity-type regions, in contact with the corresponding one of the plurality of second-conductivity-type regions, the plurality of high-concentration regions having a dopant concentration higher than a dopant concentration of the first semiconductor region.

According to the disclosure above, electric field applied to gate insulating films can be relaxed.

(6) Further, in the semiconductor device according to the disclosure, in (4) or (5) above, each of the plurality of second-conductivity-type regions has a portion between adjacent two of the plurality of third semiconductor regions in the second direction, a dopant concentration of the each of the plurality of second-conductivity-type regions being relatively lower at said portion.

According to the disclosure above, on-resistance can be reduced.

(7) Further, according to one aspect of the disclosure, a method of manufacturing a silicon carbide semiconductor device has a semiconductor substrate made of carbide, the semiconductor substrate having a first main surface and a second main surface opposite to each other; and a parallel pn layer provided in the semiconductor substrate, the parallel pn layer having a plurality of first-conductivity-type regions of a first conductivity type and a plurality of second-conductivity-type regions of a second conductivity type, repeatedly alternating with each other in a first direction parallel to the first main surface of the semiconductor substrate, is as follows. A starting substrate made of silicon carbide is prepared, the starting substrate having a first surface and a second surface opposite to each other, the second surface constituting the second main surface of the semiconductor substrate. A first process of performing epitaxy at the first surface of the starting substrate, thereby, forming a first-conductivity-type epitaxial layer of a first conductivity type, a surface of the first-conductivity-type epitaxial layer constituting the first main surface, is performed. A second process of forming, on the first-conductivity-type epitaxial layer, an ion implantation mask opened at portions corresponding to formation regions of the plurality of second-conductivity-type regions, is performed.

A third process of performing ion-implantation of a dopant of the second conductivity type, using the ion implantation mask is performed, thereby forming in the first-conductivity-type epitaxial layer, at openings of the ion implantation mask, the plurality of second-conductivity-type regions of a predetermined depth and leaving portions of the first-conductivity-type epitaxial layer excluding the plurality of second-conductivity-type regions as the plurality of first-conductivity-type regions to thereby form the parallel pn layer, is performed. A fourth process of forming a predetermined device structure between the first main surface and the parallel pn layer, is performed. A fifth process, forming a first electrode electrically connected to the device structure, is performed. A sixth process of forming a second electrode at the second main surface, is performed.

In the third process, the dopant of the second conductivity type is implanted by an acceleration energy by which the dopant of the second conductivity type punches through the ion implantation mask and a range of the dopant of the second conductivity type corresponds to a surface region of the first-conductivity-type epitaxial layer, thereby forming a diffused second-conductivity-type layer in the surface region of the first-conductivity-type epitaxial layer by the dopant of the second conductivity type, that has punched through the ion implantation mask, the diffused second-conductivity-type layer and the plurality of first-conductivity-type regions forming pn junctions through which a current passes, said current flowing in the device structure.

According to the disclosure above, no multistage epitaxy method is used to form the parallel pn layer and thus, manufacturing processes are simplified and the lead-time is shortened, whereby costs can be reduced.

(8) Further, in the semiconductor device according to the disclosure, in (7) above, in the third process, a thickness of the diffused second-conductivity-type layer is 0.8 μm or more but not more than 1.5 μm.

According to the disclosure above, formation of a short channel structure is suppressed and increases in leakage current, etc. can be suppressed. Further, removal of a diffused second-conductivity-type layer in an edge termination region is facilitated.

(9) Further, in the semiconductor device according to the disclosure, in (7) or (8) above, in the second process, a thickness of the ion implantation mask is not more than 6 μm. In the third process, the acceleration energy of the ion implantation is 1 MeV or more but not more than 8 MeV.

According to the disclosure above, the plurality of second-conductivity-type regions can be formed at a predetermined depth.

(10) Further, in the semiconductor device according to the disclosure, in any one of (7) to (9) above, the device structure includes the parallel pn layer, a first semiconductor region of the second conductivity type, a plurality of second semiconductor regions of the first conductivity type, a plurality of trenches, and a plurality of gate electrodes. The first semiconductor region is provided between the first main surface and the parallel pn layer. Each of the plurality of second semiconductor regions of the first conductivity type is selectively provided between the first main surface and the first semiconductor region. The plurality of trenches penetrate through the plurality of second semiconductor regions and first semiconductor region in the depth direction and reach the parallel pn layer. The gate electrodes are provided in the plurality of trenches, via a plurality of gate insulating films. In the fourth process, a seventh process, an eighth process, and a ninth process are performed. In the seventh process, the plurality of second semiconductor regions is selectively formed in surface regions of a diffused second-conductivity-type layer, a portion of diffused second-conductivity-type layer excluding the plurality of second semiconductor regions is left as the first semiconductor region. In the eighth process, the plurality of trenches that penetrate through the plurality of second semiconductor regions and the first semiconductor region in the depth direction and reach the parallel pn layer is formed. In the ninth process, the plurality of gate electrodes is formed in the plurality of trenches via the plurality of gate insulating films.

According to the disclosure above, manufacturing processes for the MOS-gate semiconductor device with a superjunction structure can be simplified.

(11) Further, in the semiconductor device according to the disclosure, in (10) above, in the third process, the plurality of second-conductivity-type regions are formed extending linearly in a second direction that is parallel the first main surface and orthogonal to the first direction. In the eighth process, the plurality of trenches are formed penetrating through the plurality of second semiconductor regions and the first semiconductor region in the depth direction and reaching the plurality of second-conductivity-type regions, and extending linearly in the second direction. In the seventh process, each of the plurality of second semiconductor regions is formed in a dot-shape apart from others of the plurality of second semiconductor regions in the second direction, along sidewalls of the plurality of trenches. Before the ninth process, a dopant of the first conductivity type is implanted into the sidewalls of the plurality of trenches from a direction oblique to the first main surface, thereby forming in the plurality of second-conductivity-type regions, at positions facing the plurality of second semiconductor regions in the depth direction and closer to the second main surface than is the first semiconductor region, a plurality of third semiconductor regions of the first conductivity type, penetrating through the plurality of second-conductivity-type regions in the first direction and being in contact with the plurality of first-conductivity-type regions.

According to the disclosure above, a MOS-gate semiconductor device having a superjunction structure and a lower on-resistance can be fabricated.

Findings underlying the present disclosure are discussed. A silicon carbide semiconductor device of a reference example has a semiconductor substrate made of silicon carbide (SiC) and a trench gate structure in the semiconductor substrate, at a front surface of the semiconductor substrate, and is a vertical SJ-MOSFET with SJ structure having a parallel pn layer as a drift layer. The parallel pn layer is formed by n-type column regions and p-type column regions that are repeatedly disposed alternating with each other in a direction parallel to the front surface of the semiconductor substrate. The parallel pn layer is a portion of the drift layer toward n⁺-type source regions and is formed by a multistage epitaxy method. The multistage epitaxial method is a method in which epitaxial layers are grown by epitaxy (stacked) in multiple stages, and diffusion regions of a same conductivity type are selectively formed in each epitaxial layer by ion implantation so as to be adjacent to each other in a depth direction Z.

In particular, as described in International Publication No. WO 2020/110514, in the formation of the parallel pn layer, an n-type epitaxial layer constituting the drift layer is grown by epitaxy in multiple stages and at each stage, a p-type dopant is implanted using an ion implantation mask. P-type regions constituting p-type column regions are selectively formed in each n-type epitaxial layer by ion-implantation of a p-type dopant. Portions of the n-type epitaxial layers between adjacent p-type column regions are free of ion implantation and remain an n-type and constitute the n-type column regions. The ion implantation mask has openings at portions corresponding to formation regions of the p-type column regions and is formed each time ion implantation is performed. The ion implantation masks have a thickness that can block the implanted p-type dopants and achieve implantation depths with a predetermined degree of accuracy at the openings.

For example, when a p-type dopant of the ion implantation for forming the p-type column regions is assumed to be aluminum (Al) and the maximum acceleration energy is assumed to be about 700 keV, the depth reached by the implanted Al (depth from an ion implantation surface) is a maximum of about 0.7 μm. Thus, as the drift layer, the n-type epitaxial layers of the second and subsequent stages of epitaxial growth each have a thickness of about 0.65 μm of less. When the ion implantation mask for forming the p-type column regions are an oxide film (silicon oxide (SiO₂) film) having a thickness of about 2 μm or a resist film having a thickness of about 3 μm, under the described conditions, the thickness is capable of blocking the implanted Al and the p-type column regions can be formed to have accurate patterning dimensions.

By ion-implanting Al under such conditions, using an ion implantation mask, the implanted Al is blocked by the ion implantation mask and does not reach the n-type epitaxial layer below the ion implantation mask. The implanted p-type dopant being blocked by the ion implantation mask is when a p-type dopant concentration in a portion of the n-type epitaxial layer covered by the ion implantation mask is not more than 5×10¹³/cm³, which is lower limit of detection by secondary ion mass spectrometry (SIMS).

As described, in the method of manufacturing the silicon carbide semiconductor device of the reference example, during formation of the parallel pn layer, the stacking of n-type epitaxial layers, the formation of an ion implantation mask opened at portions corresponding to formation regions of the p-type column regions, the ion-implantation of a p-type dopant, and the removal of the ion implantation mask are repeatedly performed in the state sequence until the parallel pn layer has a predetermined thickness and thus, the number of processes increases thereby increasing the manufacturing cost. In an instance in which a predetermined device structure such as the trench gate structure is formed on the parallel pn layer, epitaxial layers of a predetermined number of stages are further grown (stacked) on the parallel pn layer by epitaxial growth and thus, the manufacturing cost further increases. Thus, in the present embodiment, the manufacturing processes are simplified and costs are reduced.

For example, when the thickness of an n-type epitaxial layer grown by one stage of epitaxy is thick and a p-type dopant is implanted by a high acceleration energy, while the number of times that the above processes are repeated by the multistage epitaxy method can be reduced, accurate patterning an ion implantation mask that is thick enough to prevent passage of the p-type dopant implanted by a high acceleration energy is difficult. On the other hand, the present inventors found that using the passing of a p-type dopant implanted by a high acceleration energy through the ion implantation mask, a parallel pn layer having a predetermined charge amount can be formed with dimensional accuracy by fewer processes than the method of manufacturing the silicon carbide semiconductor device of the reference example.

Embodiments of a silicon carbide semiconductor device and a method of manufacturing a silicon carbide semiconductor device according to the present disclosure are described in detail with reference to the accompanying drawings. In the present description and accompanying drawings, layers and regions prefixed with n or p mean that majority carriers are electrons or holes. Additionally, + or − appended to n or p means that the dopant concentration is higher or lower, respectively, than layers and regions without + or −. In the description of the embodiments below and the accompanying drawings, main portions that are identical are given the same reference numerals and are not repeatedly described.

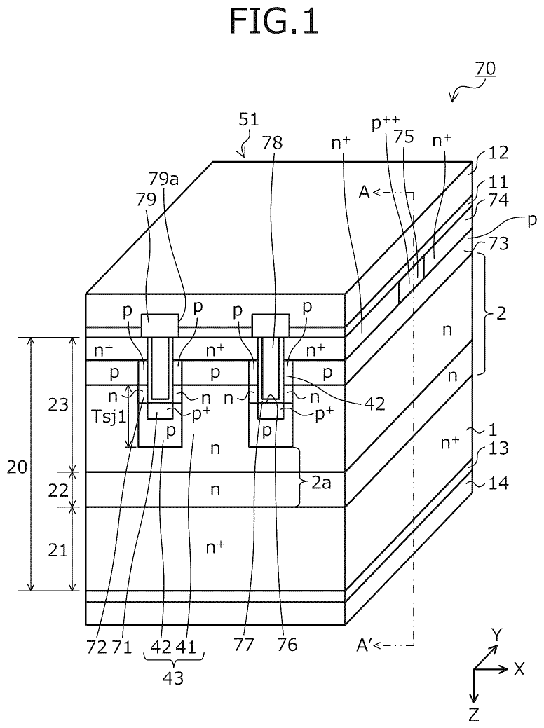

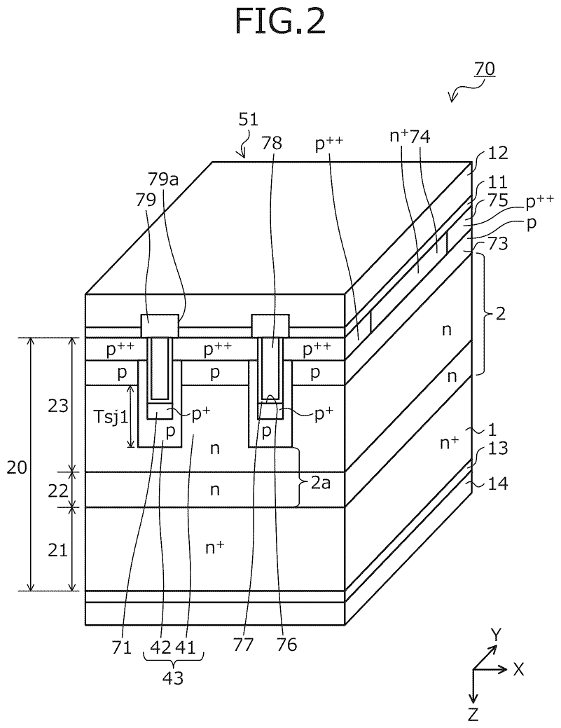

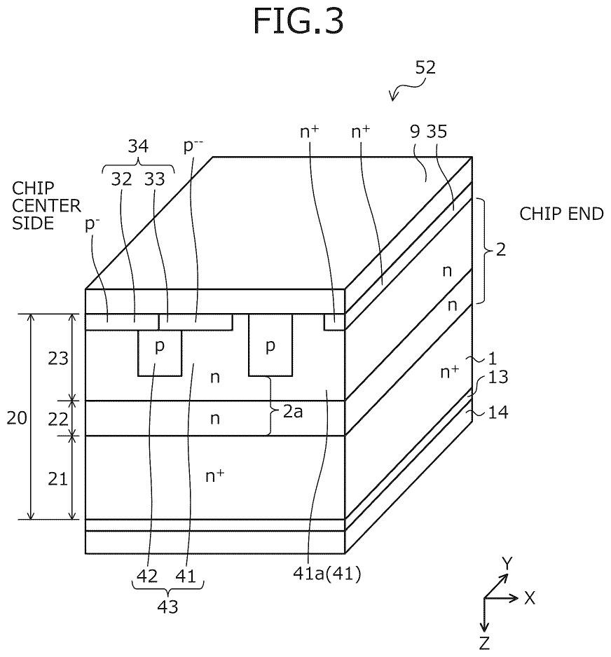

Herein, a silicon carbide semiconductor device according to a first embodiment solving the problems above are described. FIGS. 1 to 3 are perspective views depicting a structure of the silicon carbide semiconductor device according to the first embodiment. In FIGS. 1 and 2, a structure of an active region 51 is depicted while in FIG. 3, a structure of an edge termination region 52 is depicted. FIG. 2 depicts a cross-section along cutting line A-A′ in Fig. A silicon carbide semiconductor device 70 according to the first embodiment depicted in FIGS. 1 to 3 is a vertical SJ-MOSFET with a SJ structure having a parallel pn layer 43 as a drift layer 2, the carbide semiconductor device 70 further has a semiconductor silicon carbide (SiC) substrate (semiconductor chip) 20 and a trench gate structure (device structure) provided in the semiconductor substrate 20, at a front surface of the semiconductor substrate 20.

The semiconductor substrate 20 is formed by sequentially growing n-type epitaxial layers 22, 23 constituting the drift layer 2, at a front surface of an n⁺-type starting substrate 21 made of SiC, by epitaxy. The semiconductor substrate 20 has, as the front surface, a first main surface having the n-type epitaxial layer 23 and, as a back surface, a second main surface (back surface of the n⁺-type starting substrate 21) having the n⁺-type starting substrate 21. The n⁺-type starting substrate 21 constitutes an n⁺-type drain region 1. The active region 51 is a region through which a main current (drift current) flows when the device (MOSFET) is in an on-state and in which multiple unit cells (functional units of the device) each having a same structure (the trench gate structure) are disposed adjacent to each other.

The edge termination region 52 is a region between the active region 51 and an end of the semiconductor substrate 20 (chip end), and surrounds a periphery of the active region 51. In the edge termination region 52, a predetermined voltage withstanding structure 34 is provided. The voltage withstanding structure 34 has a function of relaxing electric field of a front side of the semiconductor substrate 20, in the drift layer 2 near an outer periphery of the active region 51 and thereby sustaining a breakdown voltage. The breakdown voltage is an upper limit of an operating voltage at which no malfunction or destruction of the device occurs. In FIG. 3, a junction termination extension (JTE) structure is depicted as the voltage withstanding structure 34.

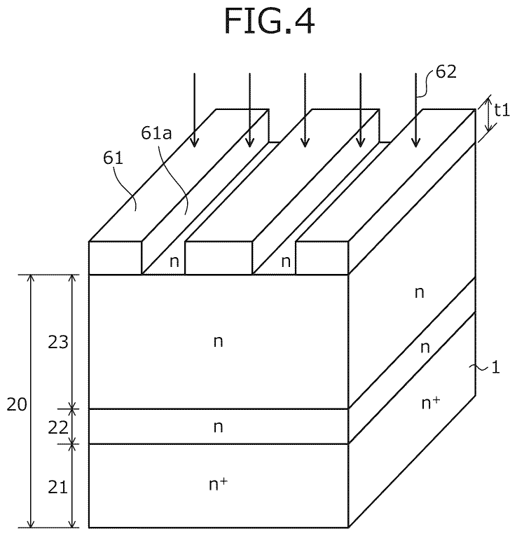

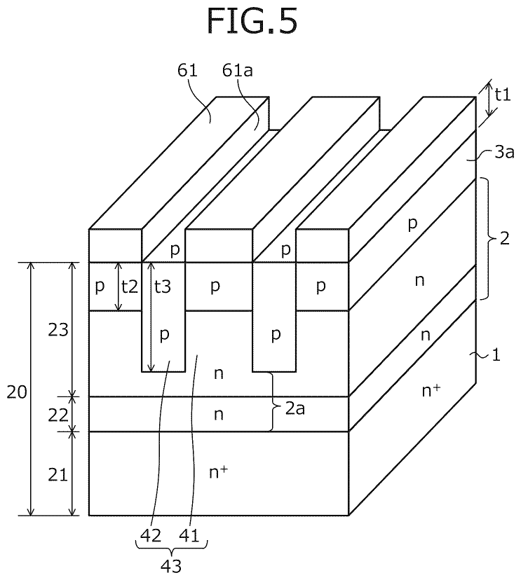

The drift layer 2 is provided between and in contact with a later-described p-type base region (first semiconductor region) 73 and the n⁺-type drain region 1. At least a portion of the drift layer 2 facing the p-type base region 73 (the front surface of the semiconductor substrate 20) constitutes the parallel pn layer 43. As described hereinafter, the parallel pn layer 43 is formed by epitaxial growth (formation) of the n-type epitaxial layer 23 of a first stage and one session of an ion implantation process 62 of a p-type dopant (dopant of a second conductivity type) to the n-type epitaxial layer 23 (refer to later-described FIGS. 4, 5). The ion implantation process 62 is one session of ion implantation by a high acceleration energy or one session of at least one stage of multistage ion implantation with a high acceleration energy.

The parallel pn layer 43 is formed by n-type regions (n-type column regions (first-conductivity-type regions)) 41 and p-type regions (p-type column regions (second-conductivity-type regions)) 42 disposed repeatedly alternating with each other in a first direction X parallel to the front surface of the semiconductor substrate 20. The n-type column regions 41 and the p-type column regions 42 are disposed extending linearly in a second direction Y orthogonal to the first direction X and parallel to the front surface of the semiconductor substrate 20. The parallel pn layer 43 is disposed in substantially a same layout spanning the active region 51 and the edge termination region 52. The n-type column regions 41 extend in the depth direction Z from a lower surface (end facing the n⁺-type drain region 1) of the p-type base region 73 and reaches an n-type buffer region 2a or the n⁺-type drain region 1. The p-type column regions 42 extend in the depth direction Z from lower surfaces of n⁺-type source regions 74 and p⁺⁺-type contact regions 75 and reach the n-type buffer region 2a or the n⁺-type drain region 1.

Of the n-type column regions 41 and the p-type column regions 42 of the parallel pn layer 43 repeatedly alternating with each other, an outermost one (closest to the chip end) is one of the n-type column regions 41 (hereinafter, n-type outer peripheral column region 41a) (refer to FIG. 3). The n-type outer peripheral column region 41a is exposed at the chip end (side surface). The n-type outer peripheral column region 41a is provided along an outer periphery of the semiconductor substrate 20 and surrounds a portion farther inward (center (chip center) side of the semiconductor substrate 20) than is the n-type outer peripheral column region 41a. The n-type outer peripheral column region 41a is in contact with both ends of each of the other the n-type column regions 41 and both ends of each of the p-type column regions 42.

A thickness Tsj1 of the parallel pn layer 43 is equivalent to a distance from an interface with the p-type base region 73 (a later-described p-type dopant punch-through layer 3a) to a lower surface of one of the p-type column regions 42. A depth of the lower surfaces of the p-type column regions 42 is a maximum depth that a p-type dopant implanted by the ion implantation process 62 for forming the p-type column regions 42 reaches (refer to FIG. 4). Provided the n-type column regions 41 and the p-type column regions 42 adjacent thereto are roughly charge-balanced (in equilibrium), a width of the n-type column regions 41 and a width of the p-type column regions 42 in a lateral direction (the first direction X) and dopant concentration profiles thereof can be suitably set.

For example, in a cross-section view, the widths of the n-type column regions 41 and the p-type column regions 42 in the lateral direction may exhibit substantially uniform linear shapes in the depth direction Z. In a cross-sectional view, a width of each of the p-type column regions 42 in the lateral direction may exhibit an inverse trapezoidal shape that is narrower closer to the n⁺-type drain region 1 (the back surface of the semiconductor substrate 20) and corresponding to the shape of each of the p-type column regions 42 in the cross-sectional view, the width of each of the n-type column regions 41 in the lateral direction may be wider closer to the n⁺-type drain region 1. The dopant concentration profile of the p-type column regions 42 may exhibit a box profile in which the dopant concentration is substantially uniform in the depth direction Z or may have a predetermined gradient in the depth direction Z.

The n-type column regions 41 and the p-type column regions 42 adjacent thereto being roughly charge-balanced means that an amount of charge expressed by a product of the width in the lateral direction and the carrier concentration (concentration of activated n-type dopants) of the n-type column regions 41 and an amount of charge expressed by a product of the width in the lateral direction and the carrier concentration (concentration of activated p-type dopants) of the p-type column regions 42 are roughly balanced. The width being substantially uniform, the dopant concentrations being substantially uniform, and the amounts of charge being roughly balanced means that the widths are the same, the dopant concentrations are the same, and the amounts of charge are the same within ranges that include an allowance for error due to process variation, that is, each at least being within a range of ±5%.

In the n-type epitaxial layers 22, 23, a portion between the parallel pn layer 43 and the n⁺-type drain region 1 may be the n-type buffer region (n-type region not part of the SJ structure) 2a. A dopant concentration of the n-type buffer region 2a is not more than a dopant concentration of the n-type column regions 41 and preferably, may be lower than the dopant concentration of the n-type column regions 41. The dopant concentration of the n-type buffer region 2a is lower than the dopant concentration of the n-type column regions 41, whereby maintenance of the breakdown voltage is facilitated. The n-type epitaxial layer 22 may be omitted.

In the active region 51, the trench gate structure is provided between the front surface of the semiconductor substrate 20 and the parallel pn layer 43. The trench gate structure is configured by the p-type base region 73, the n⁺-type source regions (second semiconductor regions) 74, the p⁺⁺-type contact regions 75, trenches 76, gate insulating films 77, and gate electrodes 78. The p-type base region 73, the n⁺-type source regions 74, and the p⁺⁺-type contact regions 75 are diffused region formed by ion implantation in the n-type epitaxial layer 23. In the n-type epitaxial layers 22, 23, a portion excluding the p-type base region 73, the n⁺-type source regions 74, the p⁺⁺-type contact regions 75, and later-described p⁺-type regions 71 constitutes the drift layer 2.

In the active region 51, the trenches 76 face the p-type column regions 42 in the depth direction Z and are parallel to the p-type column regions 42. In other words, in the active region 51, the trenches 76 extend in stripe shapes in a direction parallel to a longitudinal direction (the second direction Y) of the p-type column regions 42. A width of each of the trenches 76 in the lateral direction (the first direction X) is narrower than a width of each of the p-type column regions 42 in the lateral direction. The trenches 76 penetrate through the n⁺-type source regions 74, the p⁺⁺-type contact regions 75, the p-type base region 73, later-described n-type current spreading regions (third semiconductor regions) 72, and the p-type column regions 42 and reach the p⁺-type regions (high-concentration regions of the second conductivity type) 71.

The gate electrodes 78 are provided in the trenches 76 via the gate insulating films 77. One unit cell is configured by one of the trenches 76 (i.e., between centers of any adjacent two mesa centers between adjacent trenches 6) or is configured between centers of any adjacent two of the trenches 76. At a depth closer to the n⁺-type drain region 1 than is the p-type base region 73, at sidewalls of the trenches 76, the n-type current spreading regions 72 and the p-type column regions 42 are exposed and repeatedly alternate with each other in the second direction Y and are in contact with the gate insulating films 77 at the sidewalls of the trenches 76.

The n⁺-type source regions 74 and the p⁺⁺-type contact regions 75 are each selectively provided between the front surface of the semiconductor substrate 20 and the p-type base region 73 and are in contact with the p-type base region 73. Between the trenches 76 that are adjacent to each other, the n⁺-type source regions 74 and the p⁺⁺-type contact regions 75 are adjacent to each other and repeatedly alternate with each other in the longitudinal direction of the trenches 76. The n⁺-type source regions 74 and the p⁺⁺-type contact regions 75 are in contact with the gate insulating films 77 at the sidewalls of the trenches 76. The p⁺⁺-type contact regions 75 may be omitted. In this instance, instead of the p⁺⁺-type contact regions 75, the p-type base region 73 reach the front surface of the semiconductor substrate 20.

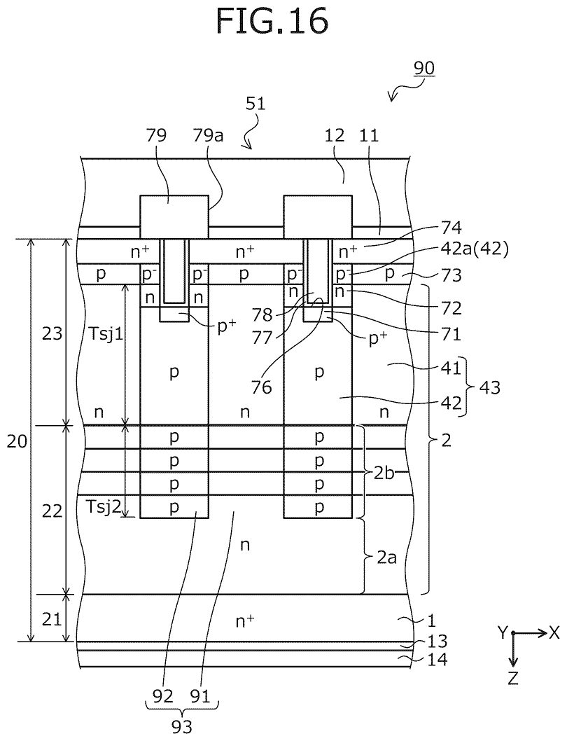

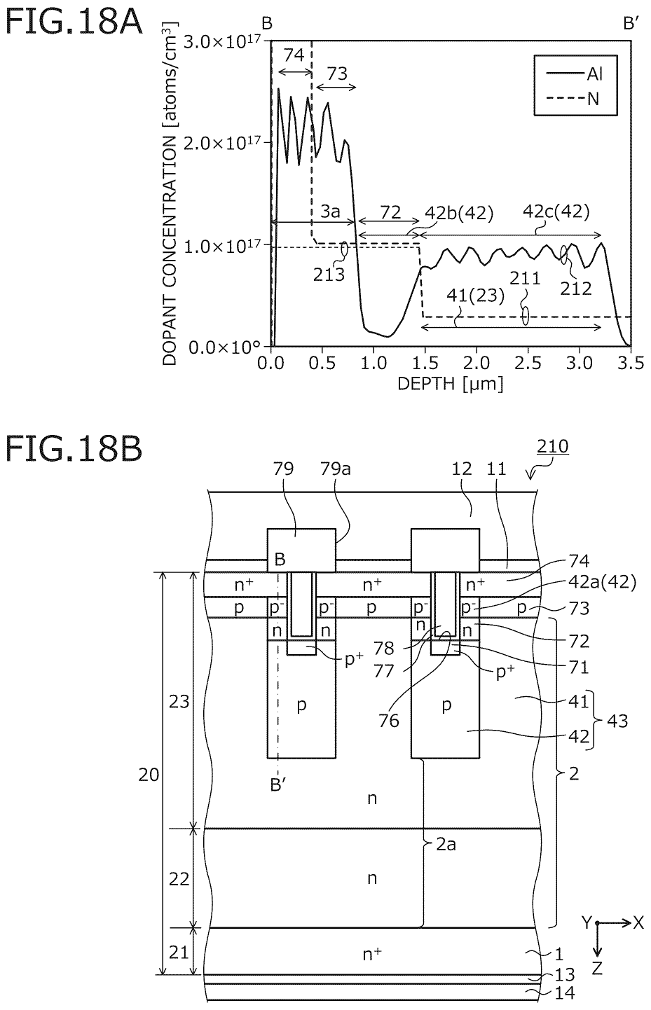

A portion of the p-type dopant punch-through layer 3a (refer to FIG. 5) excluding the n⁺-type source regions 74 and the p⁺⁺-type contact regions 75 constitutes the p-type base region 73. The p-type base region 73, at a portion (hereinafter, p⁻-type region, or “intersecting portion” where the p-type base region 73 intersects with the p-type column regions 42: refer to later-described FIGS. 16, 18B) 42a along the trenches 76, may have a p-type dopant concentration that is lower than that of the p-type base region 73. The p⁻-type regions 42a are provided between and in contact with the n⁺-type source regions 74 and the later-described n-type current spreading regions 72. In the p⁻-type regions 42a, a channel is formed when the SJ-MOSFET is on.

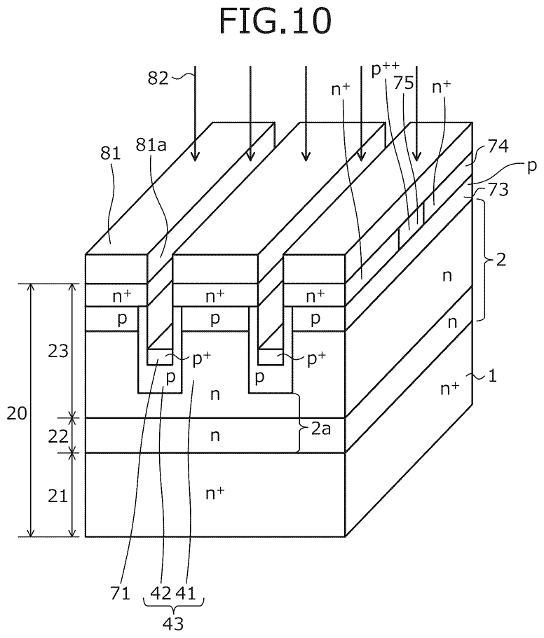

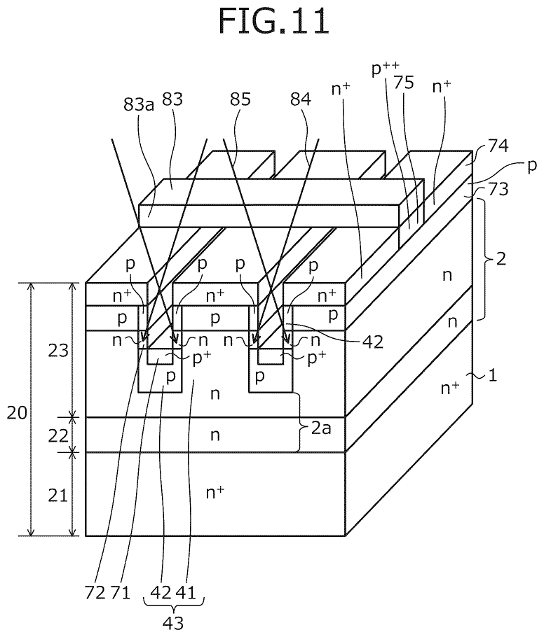

Between the p-type base region 73 and the parallel pn layer 43, the p⁺-type regions 71 and the n-type current spreading regions 72 are each selectively provided at positions closer to the n⁺-type drain region 1 than are the bottom surfaces of the trenches 6. The p⁺-type regions 71 and the n-type current spreading regions 72 are diffused regions formed by ion implantations 82, 84, 85 from inner walls of the trenches 6 to the n-type epitaxial layer 23 (refer to FIGS. 10 and 11). The p⁺-type regions 71 have a function of spreading a depletion layer when the MOSFET is off and relaxing electric field applied to the gate insulating films 77. The p⁺-type regions 71 are provided between the bottom surfaces of the trenches 76 and the p-type column regions 42 and apart from the p-type base region 73.

The p⁺-type regions 71 extend substantially a same length as the trenches 76 in the longitudinal direction of the trenches 76 and are parallel to the p-type column regions 42. The p⁺-type regions 71 are in contact with the gate insulating films 77 at the bottom surfaces of the trenches 76. The p⁺-type regions 71 is in contact with the p-type column regions 42 and surrounds a periphery of the p-type column regions 42. The p⁺-type regions 71 are fixed to a potential of the source electrode 12 via the p-type column regions 42 and the p-type base region 73. Each of the p⁺-type regions 71 may have an upper surface (surface having the p-type base region 73) in contact with the n-type current spreading regions 72. A width of each of the p⁺-type regions 71 in the lateral direction (the first direction X) is narrower than a width in the lateral direction in the p-type column regions 42.

The n-type current spreading regions 72 constitute a so-called current spreading layer (CSL) that reduces carrier spreading resistance. Directly below the n⁺-type source regions 74 (at side facing the n⁺-type drain region 1), the n-type current spreading regions 72 are provided along the sidewalls of the trenches 76, in the p-type column regions 42 that are at positions deeper than are the p-type base region 73. The n-type current spreading regions 72 are not provided directly below the p⁺⁺-type contact regions 75. Directly below the p⁺⁺-type contact regions 75, between the n-type current spreading regions 72 adjacent in the second direction Y, the p-type column regions 42 reach the n⁺-type source regions 74. In other words, the n-type current spreading regions 72 are dispersed the second direction Y.

Between the trenches 76 that are adjacent to each other and between the n-type current spreading regions 72 adjacent to each other in the first direction X, the n-type column regions 41 reach the p-type base region 73. Thus, each of the n-type current spreading regions 72 has an upper surface and a lower surface in contact with the p-type column regions 42. Each of the n-type current spreading regions 72, at both side surfaces in the second direction Y is in contact with the p-type column regions 42, at one side surface in the first direction X is in contact with one of multiple gate insulating films 7 the sidewalls of the trenches 6 and at the other side surface in the first direction X is in contact with one of the n-type column regions 41. The n-type current spreading regions 72 are disposed between a channel and the n-type column regions 41 and constitute a current path of the main current of the SJ-MOSFET. The p-type column regions 42 may have a dopant concentration that is relatively low at a portion between the n-type current spreading regions 72 adjacent to each other in the second direction Y (refer to FIG. 18A).

The trenches 76 are parallel to the p-type column regions 42, whereby the channel width (width of channel in direction along the longitudinal direction of the trenches 76) is not rate-limited by the width of the n-type column regions 41 in the lateral direction (the first direction X). The wider is the width of the n⁺-type source regions 74 in the second direction Y, the wider is the channel width and the larger is the channel area, whereby the ratio of the effective region through which the main current flows with respect to the surface area of the semiconductor substrate 20 can be increased. Further, the channel area is increased, whereby the cell pitch can be reduced to improve channel characteristics.

An interlayer insulating film 79 is provided in an entire area of the front surface of the semiconductor substrate 20 and covers the gate electrodes 78. A contact electrode (first electrode) 11 is in ohmic contact with the n⁺-type source regions 74 and the p⁺⁺-type contact regions 75 in contact holes 79a of the interlayer insulating film 79. The contact electrode 11, for example, is a nickel silicide (NixSiy, where x, y are arbitrary positive numbers) layer. The source electrode (first electrode) 12 is electrically connected to the p⁺⁺-type contact regions 75, the n⁺-type source regions 74, and the p-type base region 73 via the contact electrode 11. The contact electrode 13 is provided in an entire area of the back surface of the semiconductor substrate 20 and is in ohmic contact with the n⁺-type drain region 1 (the n⁺-type starting substrate 21). The contact electrode (second electrode) 13, for example, is a nickel silicide layer. A drain electrode (second electrode) 14 is electrically connected to the n⁺-type drain region 1 via the contact electrode 13.

In the edge termination region 52, between the front surface of the semiconductor substrate 20 and the parallel pn layer 43, for example, p-type regions 32, 33 configuring a JTE structure are provided as the voltage withstanding structure 34. In the JTE structure, the p-type regions 32, 33 are disposed adjacent to each other in concentric circles surrounding the periphery of the active region 51 so that the p-type regions 32, 33 are arranged in descending order of dopant concentration in a direction from the chip center to the chip end. The p-type regions 32, 33 are electrically connected to a p-type base region 3 and fixed to the potential of the source electrode 12 via the p-type base region 3.

Between the front surface of the semiconductor substrate 20 and the n-type outer peripheral column region 41a, an n-type channel stopper region 35 is provided closer to the chip end than is the voltage withstanding structure 34, the n-type channel stopper region 35 being apart from the voltage withstanding structure 34. The n-type channel stopper region 35 is exposed at the chip end. Between the voltage withstanding structure 34 and the n-type channel stopper region 35, the parallel pn layer 43 reaches the front surface of the semiconductor substrate 20. The voltage withstanding structure 34, the n-type channel stopper region 35, and the parallel pn layer 43 are in contact with an interlayer insulating film 9 at the front surface of the semiconductor substrate 20.

In FIG. 3, while one set of one of the n-type column regions 41 and an adjacent one of the p-type column regions 42 and the n-type outer peripheral column region 41a adjacent to and on an outer side of said adjacent one of the p-type column regions 42 are depicted between the voltage withstanding structure 34 and the n-type channel stopper region 35, the n-type column regions 41 and the p-type column regions 42 of the parallel pn layer 43 may be disposed in plural alternating with each other between the voltage withstanding structure 34 and the n-type channel stopper region 35.

Operation of the silicon carbide semiconductor device 70 according to the first embodiment (SJ-MOSFET) is described. When voltage that is positive with respect to the source electrode 12 is applied to the drain electrode 14, pn junctions (main junctions) between the p⁺⁺-type contact regions 75, the p-type base region 73, the p-type column regions 42, the p⁺-type regions 71, the n-type current spreading regions 72, the n-type column regions 41, the n-type buffer region 2a, and the n⁺-type drain region 1 are reverse biased. In this state, when the voltage applied to the gate electrodes 78 is less than a gate threshold voltage, the MOSFET maintains an off-state.

When the MOSFET is off, a depletion layer that spreads through the p⁺-type regions 71 and the p-type column regions 42 from the main junctions relaxes electric field applied to the gate insulating films 77. The spreading of the depletion layer in a direction to the chip end ensures a predetermined breakdown voltage. Further, when the MOSFET is off, pn junctions between the p-type column regions 42 and the n-type column regions 41 are reverse biased, a depletion layer spreads from the pn junctions, the parallel pn layer 43 bears the breakdown voltage. As a result, a predetermined breakdown voltage exceeding the breakdown voltage that can be realized by the dopant concentration (the n-type column regions 41) of the drift layer 2 is ensured.

On the other hand, when voltage that is positive with respect to the source electrode 12 is applied to the drain electrode 14 and a gate voltage applied to the gate electrodes 78 is at equal to the gate threshold voltage, a channel (n-type inversion layer) is formed in portions of the p-type base region 73 along the sidewalls of the trenches 76. As a result, the main current flows from the n⁺-type drain region 1, through the n-type buffer region 2a, the n-type column regions 41, the n-type current spreading regions 72, and the channel in a direction to the n⁺-type source regions 74 and the MOSFET turns on.

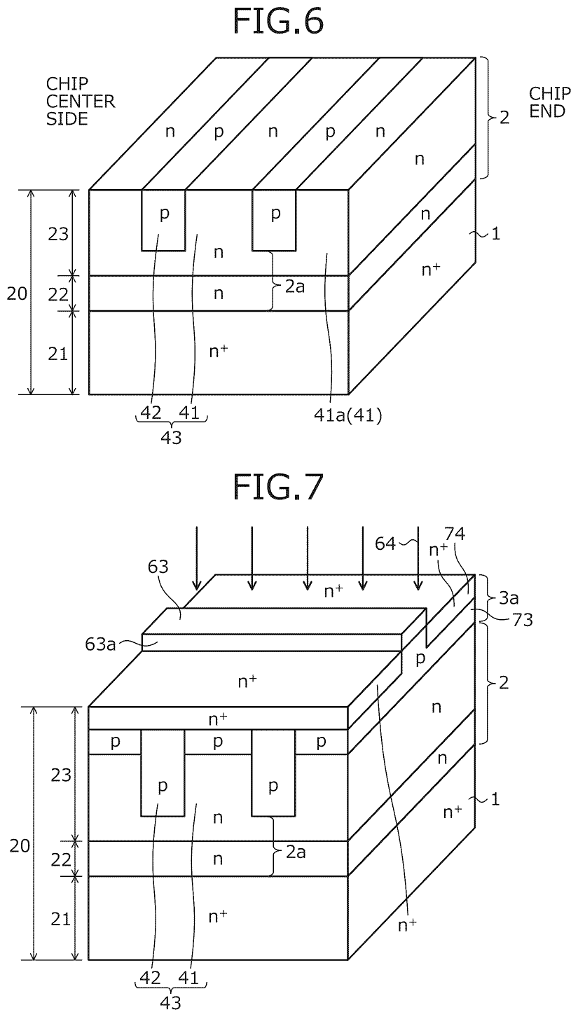

A method of manufacturing the silicon carbide semiconductor device 70 according to the first embodiment is described. FIGS. 4, 5, 6, 7, 8, 9, 10, 11, 12, 13, and 14 are perspective views depicting states of the silicon carbide semiconductor device according to the first embodiment during manufacture. FIGS. 4 and 5 depict formation processes for the parallel pn layer 43 and are common to the active region 51 and the edge termination region 52. FIGS. 7 to 14 depict states of the active region 51 during manufacture and FIG. 6 depicts a state of the edge termination region 52 during manufacture.

First, as depicted in FIG. 4, at the front surface of the n⁺-type starting substrate (starting wafer) 21 made of SiC, the n-type epitaxial layers (first-conductivity-type epitaxial layer 22, 23 constituting the drift layer 2 are sequentially grown by epitaxy (first process). The n-type epitaxial layers 22, 23 are both grown by one stage of epitaxy to a product thickness (silicon carbide semiconductor device 10) of a predetermined thickness. As a result, the semiconductor substrate (semiconductor wafer) 20 in which the n-type epitaxial layers 22, 23 are sequentially grown by epitaxy on the n⁺-type starting substrate 21 is fabricated (manufactured).

Next, an ion implantation mask 61 opened at portions corresponding to formation regions of the p-type column regions 42 is formed at the front surface of the semiconductor substrate 20 (surface of the n-type epitaxial layer 23) (second process). For example, an oxide film (SiO₂ film) or resist film can be used as the ion implantation mask 61. A thickness t1 of the ion implantation mask 61, as described hereinafter, is thin enough to allow punch-through (penetration therethrough) of a p-type dopant implanted in surface regions of the n-type epitaxial layer 23 by the ion implantation process 62 to form the p-type column regions 42. Preferably, with consideration of punch-through and to enable formation with accurate pattern dimensions, the thickness t1 of the ion implantation mask 61 may be in a range of 1.5 μm to 4.8 μm for an oxide film or a range of 1.8 μm to 6.0 μm for a resist film.

Next, a p-type dopant is implanted by the ion implantation process 62 using the ion implantation mask 61 and a high acceleration energy (for example, the maximum energy is about 1 MeV or more but not more than 8 MeV), whereby the p-type column regions 42 are formed at openings 61a of the ion implantation mask 61, the p-type column regions 42 reaching a predetermined depth in the n-type epitaxial layer 23 from the front surface of the semiconductor substrate 20 (ion-implantation surface). The p-type column regions 42 formed by the ion implantation process 62 reach a predetermined depth that that is a same as a sum of a depth of each of the n⁺-type source regions 74, a depth of the p-type base region 73, and a depth of the parallel pn layer 43 from the front surface of the semiconductor substrate 20.

Further, at this time, the p-type dopant implanted by the ion implantation process 62 is intentionally caused to punch-through the ion implantation mask 61, whereby a p-type dopant punch-through layer (diffused second-conductivity-type layer) 3a constituting the p-type base region 73 is formed in the n-type epitaxial layer 23, in an entire area at the surface thereof. In other words, the ion implantation process 62 is performed by a high acceleration energy such that, at the openings 61a of the ion implantation mask 61, the p-type column regions 42 that reach a predetermined depth in the n-type epitaxial layer 23 are formed while in portions covered by the ion implantation mask 61, the p-type dopant punch-through layer 3a is formed with surface regions of the n-type epitaxial layer 23 as the range. The gradient of the dopant concentration in the depth direction Z is the same for the p-type dopant punch-through layer 3a and lower end portions of the p-type column regions 42. Since one session of the ion implantation process 62 is by one ion implantation mask 61, a portion of each of the p-type column regions 42 at a same depth as the p-type dopant punch-through layer 3a may have a dopant concentration that is different from that of the p-type dopant punch-through layer 3a.

A thickness t2 of the p-type dopant punch-through layer 3a (thickness from the ion-implantation surface) is, for example, about 0.8 μm or more. When the thickness t2 of the p-type dopant punch-through layer 3a is less than the lower limit described above, the p-type base region 3 becomes thinner after the n⁺-type source regions 74, resulting in a short channel structure, whereby leakage current, etc. increases. Further, preferably, in the edge termination region 52, the thickness t2 of the p-type dopant punch-through layer 3a may be, for example, about 1.5 μm or less, which facilitates removal of the p-type dopant punch-through layer 3a by etching.

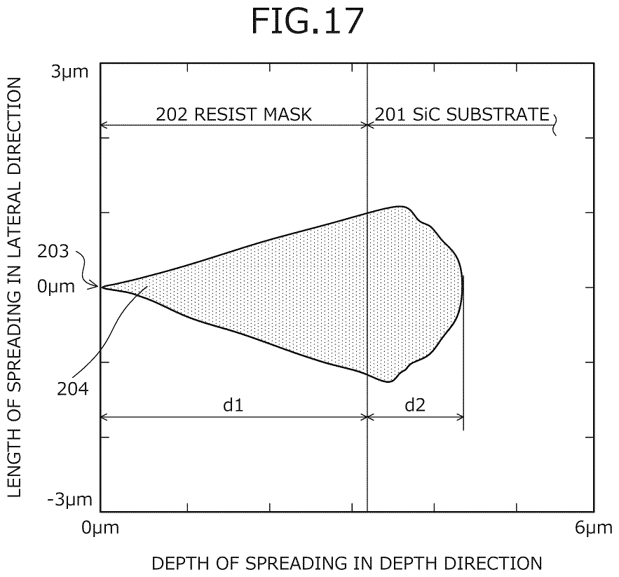

More specifically, in an instance in which a resist film is used as the ion implantation mask 61, the thickness t1 of the ion implantation mask 61 is set to about 3.2 μm and aluminum (Al), which is a p-type dopant (p-type impurity) is assumed to be implanted by the ion implantation process 62 using a high acceleration energy of, for example, about 5 MeV. Thus, it was confirmed, by simulation, that the Al implanted by the ion implantation process 62 punches-through the ion implantation mask 61 and reaches a depth of 0.8 μm in the n-type epitaxial layer 23, from the front surface of the semiconductor substrate 20 (ion-implantation surface) (refer to FIG. 17). At the openings 61a of the ion implantation mask 61, by a high acceleration energy of about 5 MeV, implanted Al reaches a depth of about 2.4 μm in the n-type epitaxial layer 23. As a result, the p-type column regions 42 of a depth t3 within a range of about 0.8 μm to 3.2 μm and deeper than the thickness t2 of the p-type dopant punch-through layer 3a can be formed by one session of the ion implantation process 62 of a high acceleration energy.

As for the multistage ion implantation in which at least one stage of the ion implantation process 62 is by a high acceleration energy, the dopant concentration profile of the p-type column regions 42 may be set to be a box profile. The multistage ion implantation is process that is divided into and performed in multiple stages by acceleration energies for which a predetermined dose of a dopant differs. The ion implantation process 62, for example, assumes multistage ion implantation by an acceleration energy within a range of about 60 keV to 8 MeV and in the multistage ion implantation, at least one stage of the ion implantation suffices to be performed by a high acceleration energy of 1 MeV or higher so the p-type column regions 42 reach a predetermined depth.

Portions of the n-type epitaxial layer 23, each between adjacent two of the p-type column regions 42 and left as an n-type free of the ion implantation process 62 and directly below the p-type dopant punch-through layer 3a constitute the n-type column regions 41. Thus, in the n-type epitaxial layer 23, the parallel pn layer 43 configured by the n-type column regions 41 and the p-type column regions 42 is formed (third process). The portions of the n-type epitaxial layer 23 left as an n-type free of the ion implantation process 62 and closer to the n⁺-type starting substrate 21 than is the parallel pn layer 43 and the n-type epitaxial layer 22 constitute the n-type buffer region 2a. The state up to here is depicted in FIG. 5.

Next, as depicted in FIG. 6, the ion implantation mask 61 is removed and thereafter, an etching mask (not depicted) opened at a portion corresponding to the edge termination region 52 is formed at the front surface of the semiconductor substrate 20. Next, the semiconductor substrate 20 is etched using the etching mask to thereby remove the p-type dopant punch-through layer 3a in the edge termination region 52, whereby in an entire area of the front surface of the semiconductor substrate 20, the parallel pn layer 43 is exposed in the entire area of the edge termination region 52. Further, the etching mask.

Next, as depicted in FIG. 7, an ion implantation mask 63 opened at portions corresponding to the n⁺-type source regions 74 is formed at the front surface of the semiconductor substrate 20. Openings 63a of the ion implantation mask 63 extend in stripe shapes in a direction orthogonal to the longitudinal direction of the p-type column regions 42. Next, an ion implantation 64 of an n-type dopant is performed using the ion implantation mask 63, whereby the n⁺-type source regions 74 are selectively formed in surface regions of the p-type dopant punch-through layer 3a. While not depicted, the ion implantation mask 63 is further opened at a portion corresponding to a formation region of the n-type channel stopper region 35 and the n-type channel stopper region 35 is formed in a surface region of the n-type outer peripheral column region 41a by the ion implantation 64. Subsequently, the ion implantation mask 63 is removed.

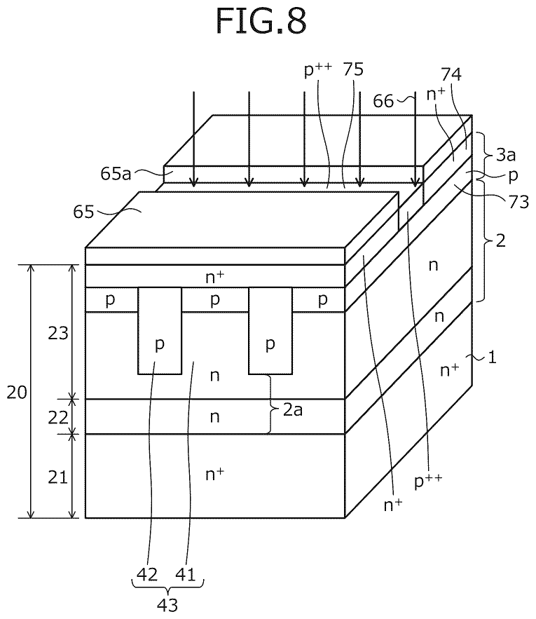

Next, as depicted in FIG. 8, at the front surface of the semiconductor substrate 20, an ion implantation mask 65 opened at portions corresponding to formation regions of the p⁺⁺-type contact regions 75 is formed. Openings 65a of the ion implantation mask 65 extend in stripe shapes in a direction orthogonal to the longitudinal direction of the p-type column regions 42. Next, an ion implantation 66 of a p-type dopant is performed using the ion implantation mask 65, whereby the p⁺⁺-type contact regions 75 are selectively formed in surface regions of the p-type dopant punch-through layer 3a. Subsequently, the ion implantation mask 65 is removed. A portion of the p-type dopant punch-through layer 3a excluding the n⁺-type source regions 74 and the p⁺⁺-type contact regions 75 constitutes the p-type base region 73 (fourth process (seventh process)).

Introduction of implantation defects in the n-type epitaxial layer 23 by the ion implantations process 64, 66 further occurs from the lower surface of the p-type dopant punch-through layer 3a and the lifetime of the n-type epitaxial layer 23 can be reduced. Moreover, the p-type column regions 42 and the trenches 76 are parallel and there is no sacrifice of channel regions, whereby resistance can be reduced.

Next, while not depicted, formation of an ion implantation mask, ion-implantation of a p-type dopant under predetermined conditions and removal of the ion implantation mask are repeatedly performed in the order stated, whereby in the edge termination region 52, in surface regions (surface regions of the parallel pn layer 43 in the edge termination region 52) at the front surface of the semiconductor substrate 20, the p-type regions 32, 33 (refer to FIG. 3) configuring the voltage withstanding structure 34 are each selectively formed. The voltage withstanding structure 34 and the n-type channel stopper region 35 suffice to be formed at any timing after the p-type dopant punch-through layer 3a in the edge termination region 52 is removed but before the parallel pn layer 43 exposed at the front surface of the semiconductor substrate 20 in the edge termination region 52 is covered by an insulating film (the gate insulating films 7, the interlayer insulating film 9, etc.).

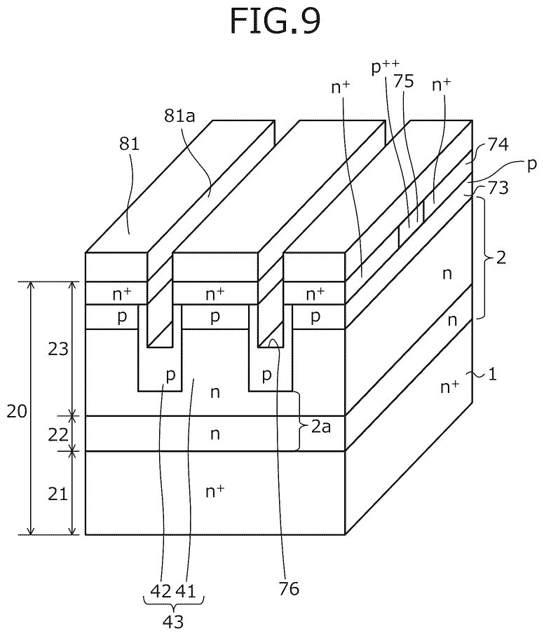

Next, as depicted in FIG. 9, at the front surface of the semiconductor substrate 20, an etching mask 81 opened at portions corresponding to formation regions of the trenches 76 is formed. Openings 81a of the etching mask 81 are parallel to the p-type column regions 42. In the openings 81a of the etching mask 81, the n⁺-type source regions 74 and the p⁺⁺-type contact regions 75 are exposed and repeatedly alternate with each other in a longitudinal direction of the openings 81a.

Next, the semiconductor substrate 20 is etched using the etching mask 81 to thereby form the trenches 76 that penetrate through the n⁺-type source regions 74 and the p⁺⁺-type contact regions 75 in the depth direction Z and reach the p-type column regions 42, the trenches 76 terminating in the p-type column regions 42, at positions closer to the n⁺-type drain region 1 than is the p-type base region 73 (fourth process (eighth process)). At positions closer to the n⁺-type drain region 1 than are the n⁺-type source regions 74, the p-type column regions 42 are exposed at an entire surface of the inner wall of each of the trenches 76.

Next, as depicted in FIG. 10, the etching mask 81 used in the formation of the trenches 76 is used as is to perform the ion implantation process 82 of a p-type dopant such as, for example, Al from a direction orthogonal to the front surface of the semiconductor substrate 20 and thereby form the p⁺-type regions 71 in surface regions of the p-type column regions 42 exposed at the bottom surfaces of the trenches 76. Subsequently, the etching mask 81 is removed.

Next, as depicted in FIG. 11, at the front surface of the semiconductor substrate 20, an ion implantation mask 83 opened at portions corresponding to formation regions of the n-type current spreading regions 72 is formed. In openings 83a of the ion implantation mask 83, the n⁺-type source regions 74 and inner walls of the trenches 76 between the n⁺-type source regions 74 that are adjacent to each other in the first direction X.

Next, the ion implantation mask 83, from a direction that is oblique relative to the front surface of the semiconductor substrate 20, ion implantation process (hereinafter, oblique ion implantations) 84, 85 of an n-type dopant (first-conductivity-type dopant) are respectively performed at both sidewalls of each of the trenches 76. The oblique ion implantation process 84, 85 invert portions of the p-type column regions 42 along the sidewalls of the trenches 76 into an n-type and thereby form the n-type current spreading regions 72.

The n-type current spreading regions 72 are formed from the sidewalls of the trenches 76 in a direction orthogonal to the sidewalls of the trenches 76, at depths reaching the n-type column regions 41. Preferably, the p-type column regions 42 may be formed so that at depth portions thereof inverted to an n-type by the oblique ion implantations 84, 85, a p-type dopant concentration is relatively lower than at other portions of the p-type column regions 42 (refer to FIG. 18A).

Further, a p-type dopant concentration of the p-type column regions 42 at portions thereof along the sidewalls of the trenches 76 may be reduced by the oblique ion implantations 84, 85. In this instance, between and in contact with the n⁺-type source regions 74 and the n-type current spreading regions 72, the p⁻-type regions 42a (refer to later-described FIGS. 16 and 18B) are formed. Subsequently, the ion implantation mask 83 is removed.

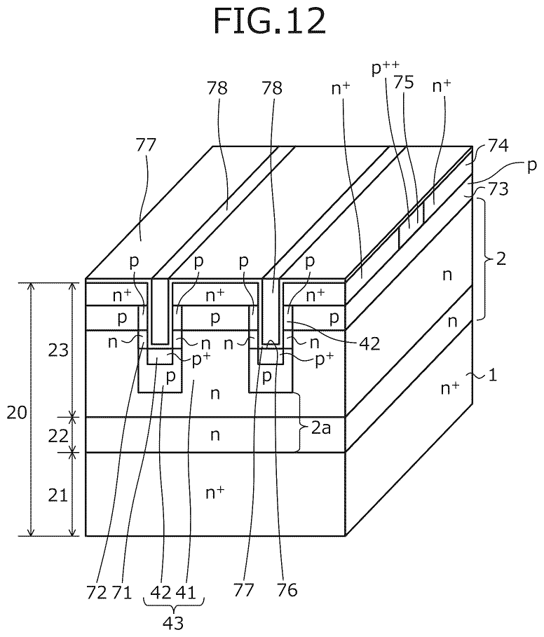

Next, as depicted in FIG. 12, the gate insulating films 77 are formed along the front surface of the semiconductor substrate 20 and the inner walls of the trenches 76. Next, for example, the gate electrodes 78 made of a polysilicon (poly-Si) are embedded in the trenches 76, on the gate insulating films 77 (fourth process (ninth process)).

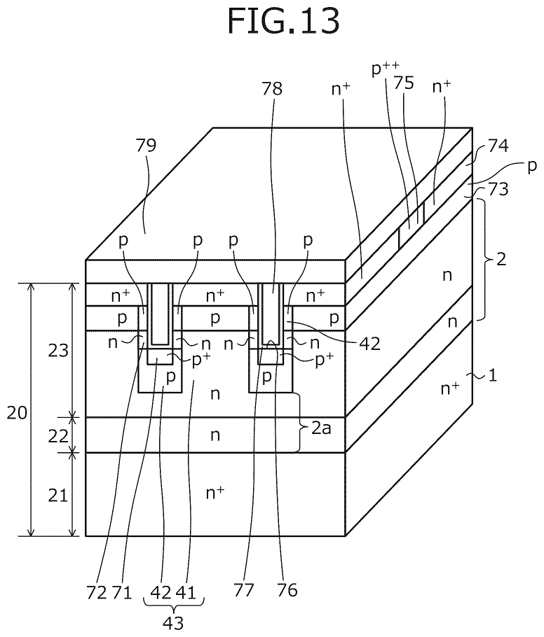

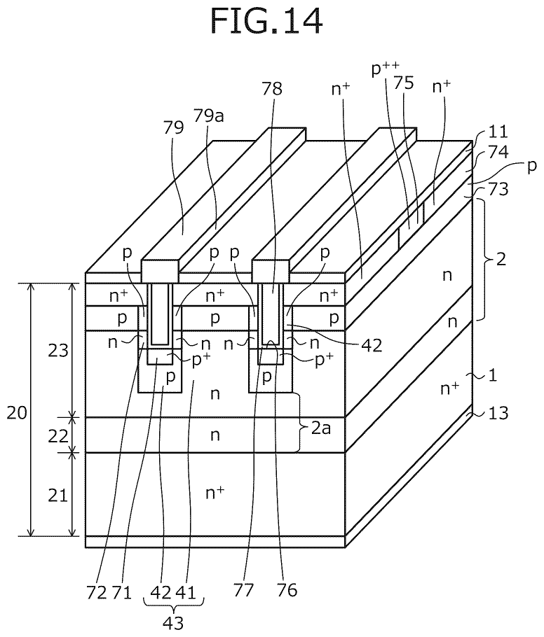

Next, as depicted in FIG. 13, the interlayer insulating film 79 is formed in an entire area of the front surface of the semiconductor substrate 20. Next, as described with reference to FIG. 14, the interlayer insulating film 79 is etched and selectively removed, whereby the contact holes 79a are formed, exposing the n⁺-type source regions 74 and the p⁺⁺-type contact regions 75.

Next, in the contact holes 79a of the interlayer insulating film 79, the contact electrode 11, which in ohmic contact with the front surface of the semiconductor substrate 20, is formed (fifth process). The contact electrode 13, which is in ohmic contact with the back surface of the semiconductor substrate 20, is formed (sixth process). The state up to here is depicted in FIG. 14. Further, at both main surfaces of the semiconductor substrate 20, the source electrode 12 and the drain electrode 14 are formed respectively (fifth and sixth processes). Thereafter, the semiconductor wafer (the semiconductor substrate 20) is diced (cut) into individual chips, thereby completing depicted silicon carbide semiconductor device 70 in FIGS. 1 to 3.

As described above, according to the first embodiment, when configuring the drift layer by a parallel pn layer, p-type column regions of a predetermined depth are formed by one session of ion implantation process by a high acceleration energy (or at least one session of multistage ion implantation in which one stage uses a high acceleration energy). At this time, the implanted p-type dopant is intentionally caused to punch-through the ion implantation mask to thereby form a p-type dopant punch-through layer constituting the p-type base region. In other words, when the parallel pn layer is formed, no multistage epitaxy method is used and thus, manufacturing processes are simplified and the lead-time is shortened, whereby costs can be reduced.

Further, according to the first embodiment, to form the p-type column regions, the implanted p-type regions can punch-through the ion implantation mask without adverse effects and thus, the thickness of the ion implantation mask can be set to be relatively thin. As a result, the cost of processes for forming the ion implantation masks can be reduced. Further, according to the first embodiment, the thickness of the ion implantation mask used in the ion implantation for forming the p-type column regions is thin, whereby the ion implantation mask can be formed to have patterning with dimensional accuracy, whereby the accuracy of the dimensions of the p-type column regions is improved. Thus, manufacturing variation can be reduced.

Further, according to the first embodiment, the longitudinal direction of the trenches 76 is parallel to the longitudinal direction of the p-type column regions 42, whereby the channel width is not rate-limited by the width of each of the n-type column regions in the lateral direction, thereby enabling the channel area to be increased. As a result, channel characteristics are improved, enabling reduction of the cell pitch.

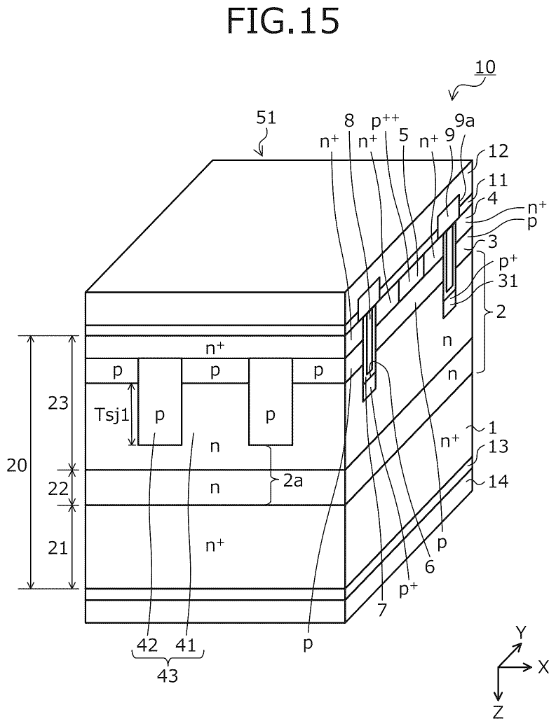

The silicon carbide semiconductor device according to a second embodiment solving the problems above is described. FIG. 15 is a perspective view depicting the structure of the silicon carbide semiconductor device according to the second embodiment. FIG. 15 depicts the structure of the active region 51. The structure of the edge termination region 52 is the same as that of the first embodiment (refer to FIG. 3). The silicon carbide semiconductor device 10 according to the second embodiment differs from the silicon carbide semiconductor device 70 according to the first embodiment (refer to FIGS. 1 and 2) in that the longitudinal direction (the first direction X) of the trenches 6 is orthogonal (the second direction Y) to the longitudinal direction of the p-type column regions 42. The configuration of the parallel pn layer 43 is the same as that of the first embodiment.

In the second embodiment, the trenches 6 penetrate through the n⁺-type source regions 4, the p-type base region 3, and the parallel pn layer 43 in the depth direction Z and reach the p⁺-type regions 31. Each of the trenches 6 extends in a stripe shape in the first direction X in the active region 51. At a deep position closer to the n⁺-type drain region 1 than is the p-type base region 3, the n-type column regions 41 and the p-type column regions 42 repeatedly alternate with each in the first direction X and are exposed at sidewalls of each of the trenches 6. The n-type column regions 41 and the p-type column regions 42 are in contact with the gate insulating films 7 at the sidewalls of the trenches 6. Excluding the trenches 6, configuration of the trench gate structure is substantially the same as corresponding regions of the trench gate structure of the first embodiment.

In particular, in the trenches 6, gate electrodes 8 are respectively provided via the gate insulating films 7. One unit cell is configured by one of the trenches 6. One unit cell may be configured between the respective centers of adjacent two of the trenches 6. In the active region 51, the p-type base region 3 is provided in an entire area between the front surface of the semiconductor substrate 20 and the parallel pn layer 43 and is in contact with the n-type column regions 41 and the p-type column regions 42. The p-type base region 3 is in contact with the gate insulating films 7 at the sidewalls of the trenches 6. Similar to the p-type base region 73 of the first embodiment (refer to FIGS. 4, 5), the p-type base region 3 is formed concurrently with the p-type column regions 42.

The n⁺-type source regions 4 and p⁺⁺-type contact regions 5 are selectively provided between the front surface of the semiconductor substrate 20 and the p-type base region 3 and are in contact with the p-type base region 3. The n⁺-type source regions 4 and the p⁺⁺-type contact regions 5 extend in the longitudinal direction of the trenches 6 and have substantially a same length as that of the trenches 6, the n⁺-type source regions 4 and the p⁺⁺-type contact regions 5 are adjacent to each other in the second direction Y. The n⁺-type source regions 4 are in contact with the gate insulating films 7 at the sidewalls of the trenches 6. The p⁺⁺-type contact regions 5 are disposed apart from the trenches 6. The p⁺⁺-type contact regions 5 may be omitted. In this instance, instead of the p⁺⁺-type contact regions 5, the p-type base region 3 reach the front surface of the semiconductor substrate 20.

Between the p-type base region 3 and the parallel pn layer 43, the p⁺-type regions 31 are selectively provided at deep positions closer to the n⁺-type drain region 1 than are the bottom surfaces of the trenches 6. The p⁺-type regions 31 have a function of causing a depletion layer to spread, protecting the gate insulating films 7 at the bottom surfaces of the trenches 6, and relaxing electric field applied to the gate insulating films 7, when the MOSFET is off. The p⁺-type regions 31, similar to the p⁺-type regions 71 of the first embodiment (refer to FIG. 10), are diffused regions formed by ion implantation from the bottom surfaces of the trenches 6 to the n-type epitaxial layer 23. The p⁺-type regions 31 extend in the longitudinal direction (the first direction X) of the trenches 6 and have substantially the same length as that of the trenches 6. The longitudinal direction of the p⁺-type regions 31 is orthogonal to the longitudinal direction of the p-type column regions 42.

The p⁺-type regions 31 are provided apart from the p-type base region 3 and face the bottom surfaces of the trenches 6 in the depth direction Z. The p⁺-type regions 3 are in contact with the gate insulating films 7 at the bottom surfaces of the trenches 6. A width of each of the p⁺-type regions 31 in the lateral direction is, for example, equal to or greater than a width of each of the trenches 6 in the lateral direction. The p⁺-type regions 31 are in contact with the parallel pn layer 43 (the n-type column regions 41 and the p-type column regions 42) and surround a periphery of the parallel pn layer 43, in a plan view. The p⁺-type regions 31 are connected to the potential of the source electrode 12 via the p-type column regions 42 and the p-type base region 3. Lower surfaces of the p⁺-type regions 31 are at positions closer to the p-type base region 3 than is the lower surface of the parallel pn layer 43. The n-type current spreading regions are not provided.

The interlayer insulating film 9 is provided in an entire area of the front surface of the semiconductor substrate 20 and covers the gate electrodes 8. The contact electrode 11 is in ohmic contact with the n⁺-type source regions 4 and the p⁺⁺-type contact regions 5 in contact holes 9a of the interlayer insulating film 9. The material of the contact electrode 11 is the same as that of the first embodiment. The source electrode 12 is electrically connected to the p⁺⁺-type contact regions 5, the n⁺-type source regions 4, and the p-type base region 3 via the contact electrode 11. Configuration of the contact electrode 13 and the drain electrode 14 at the back surface of the semiconductor substrate 20 is a same as that of the first embodiment.

A method of manufacturing the silicon carbide semiconductor device 10 according to the second embodiment can be implemented by changing the pattern of the etching mask for forming the trenches 6, performing ion-implantation of a p-type dopant for forming the p⁺-type regions 31 at the bottom surfaces of the trenches 6, and omitting the ion implantation for forming the n-type current spreading regions in the method of manufacturing the silicon carbide semiconductor device 70 according to the first embodiment.

In particular, first, similar to the first embodiment, the processes from forming the parallel pn layer 43 to forming the n⁺-type source regions 4 and the p⁺⁺-type contact regions 5 are sequentially performed (refer to FIGS. 4 to 8). The method of forming the n⁺-type source regions 4 and the p⁺⁺-type contact regions 5 is as a same as that for forming the n⁺-type source regions 74 and the p⁺⁺-type contact regions 75 of the first embodiment. Similar to the first embodiment, without removing the p-type dopant punch-through layer 3a (refer to FIG. 5), a portion excluding the n⁺-type source regions 4 and the p⁺⁺-type contact regions 5 constitutes the p-type base region 3 (i.e., in FIGS. 7 and 8, reference numerals 73 to 75 are changed to reference numerals 3 to 5, respectively).

In the second embodiment, the introduction of implantation defects in to the n-type epitaxial layer 23 by the ion implantation further occurs from the lower surface of the p-type dopant punch-through layer 3a and the lifetime of the n-type epitaxial layer 23 can be reduced. Furthermore, the area below the p-type dopant punch-through layer 3a (area toward the n⁺-type drain region 1) constitutes the parallel pn layer 43 configured by the n-type column regions 41 and the p-type column regions 42 and thus, can be formed with dimensional accuracy.

Next, at the front surface of the semiconductor substrate 20, an etching mask opened at portions corresponding to formation regions of the trenches 6 are formed. The openings of the etching mask extend in stripe-shapes in a direction orthogonal to the longitudinal direction of the p-type column regions 42. In the openings of the etching mask, only the n⁺-type source regions 4 are exposed. Next, the semiconductor substrate 20 is etched using the etching mask, thereby forming the trenches 6 that penetrate through the n⁺-type source regions 4 and the p-type base region 3 in the depth direction Z and terminate in the parallel pn layer 43. At the inner walls of the trenches 6, the n-type column regions 41 and the p-type column regions 42 repeatedly alternate with each other in the longitudinal direction of the trenches 6 and are exposed. At the sidewalls of the trenches 6, the n-type column regions 41 are adjacent to the lower surface of the p-type base region 3 and the p-type column regions 42 are adjacent to the lower surfaces of the n⁺-type source regions 4.

Next, the etching mask used in the formation of the trenches 6 is used as is to ion-implant a p-type dopant such as, for example, Al, at the front surface of the semiconductor substrate 20, whereby the p⁺-type regions 31 are formed in surface regions of the parallel pn layer 43 exposed at the bottom surfaces of the trenches 6. Subsequently, the etching mask is removed. Next, along the front surface of the semiconductor substrate 20 and the inner walls of the trenches 6, the gate insulating films 7 are formed. Next, in the trenches 6, the gate electrodes 8 are embedded therein, on the gate insulating films 7. Next, in an entire area of the front surface of the semiconductor substrate 20, the interlayer insulating film 9 is formed. Next, the interlayer insulating film 9 is selectively removed by etching, whereby the contact holes 9a are formed and the n⁺-type source regions 4 and the p⁺⁺-type contact regions 5 are exposed.

Next, in the contact holes 9a of the interlayer insulating film 9, the contact electrode 11 that is in ohmic contact with the front surface of the semiconductor substrate 20 is formed. Thereafter, similar to the first embodiment, the process of forming the contact electrode 13 and subsequent processes are sequentially performed, whereby the silicon carbide semiconductor device 10 depicted in FIG. 15 is completed.

As described, according to the second embodiment, even in an instance in which the longitudinal direction of the trenches is orthogonal to the longitudinal direction of the p-type column regions, effects similar to those of the first embodiment can be obtained.

Further, according to the second embodiment, the longitudinal direction of the trenches is orthogonal to the longitudinal direction of the p-type column regions. Thus, the p-type column regions relax the electric field applied to the gate insulating films. Further, the n-type column regions reduce the carrier spreading resistance in the second direction, whereby JFET (Junction FET) resistance is reduced. Thus, for example, in International Publication No. WO 2020/110514, while the n-type current spreading regions and the p⁺-type regions for relaxing electric field are provided between adjacent trenches near the bottom surfaces of the trenches, according to the second embodiment, these regions may be omitted. Thus, the manufacturing process is further simplified.

The silicon carbide semiconductor device according to a third embodiment solving the problems above is described. FIG. 16 is a cross-sectional view depicting the structure of the silicon carbide semiconductor device according to the third embodiment. In a silicon carbide semiconductor device 90 according to the third embodiment, before the process for forming the parallel pn layer (hereinafter, first parallel pn layer) 43 of the silicon carbide semiconductor device 70 according to the first embodiment (refer to FIGS. 1 and 2), a second parallel pn layer 93 is formed by a multistage epitaxy method, whereby in the drift layer 2, a portion 2b thereof in contact with the lower surface of the first parallel pn layer 43 is the second parallel pn layer 93 formed by the multistage epitaxy method.

In particular, in the third embodiment, the first parallel pn layer 43 reaches an interface between the n-type epitaxial layers 22, 23 in the depth direction Z. The second parallel pn layer 93 is formed in the n-type epitaxial layer 22 by a multistage epitaxy method, similar to the parallel pn layer of the reference example described above. The second parallel pn layer 93 has an upper surface in contact with the first parallel pn layer 43. A sum of the thickness Tsj1 of the first parallel pn layer 43 and a thickness Tsj2 of the second parallel pn layer 93 is a total thickness of the parallel pn layer of the drift layer 2. In the n-type epitaxial layer 22, a portion thereof between the second parallel pn layer 93 and the n⁺-type drain region 1 may be the n-type buffer region 2a.

The second parallel pn layer 93 is configured by n-type column regions 91 and p-type column regions 92 disposed repeatedly alternating with each other in the first direction X. The n-type column regions 91 and the p-type column regions 92, when viewed from the front surface of the semiconductor substrate 20, are disposed in substantially a same layout as that of the n-type column regions 41 and the p-type column regions 42 of the first parallel pn layer 43. The n-type column regions 91 and the p-type column regions 92 each have an upper surface in contact with the n-type column regions 41 and the p-type column regions 42 and a lower surface in contact with the n-type buffer region 2a or the n⁺-type drain region 1.

A method of manufacturing the silicon carbide semiconductor device 90 according to the third embodiment can be implemented by adding a process of forming the second parallel pn layer 93 by a multistage epitaxy method to the method of manufacturing the silicon carbide semiconductor device 70 according to the first embodiment (FIG. 4 to 14). In other words, at the front surface of the n⁺-type starting substrate 21, in the n-type epitaxial layer 22, after an n-type epitaxial layer of a first stage and constituting the n-type buffer region 2a is formed by epitaxial growth but before the n-type epitaxial layer 23 is formed by epitaxial growth, the second parallel pn layer 93 is formed.

The second parallel pn layer 93 is formed by selectively forming p-type regions constituting the p-type column regions 92 by ion-implantation of a p-type dopant performed for each stage of the multi-stage epitaxial growth into which the n-type epitaxial layer 22 is divided (herein, three stages in addition to the first stage forming the n-type buffer region 2a) by the multistage epitaxy method. Thereafter, the n-type epitaxial layer 23 is formed on the second parallel pn layer 93 by epitaxial growth and, similar to the first embodiment, the process of forming the first parallel pn layer 43 and the subsequent processes are sequentially performed.

In the silicon carbide semiconductor device 90 according to the third embodiment, the second embodiment (refer to FIG. 15) may be applied and the longitudinal direction of the trenches 76 may be orthogonal to the longitudinal direction of the p-type column regions 42, 92.

As described, according to the third embodiment, effects similar to those of the first and second embodiments can be obtained by the first parallel pn layer. Further, according to the third embodiment, in an instance in which a length of each of the p-type column regions of the first parallel pn layer in the depth direction is insufficient with respect to design values, by the p-type column regions of the second parallel pn layer formed between the first parallel pn layer and the n⁺-type drain region by the multistage epitaxy method, a total length (i.e., a total thickness of the parallel pn layer) in a depth direction of the p-type column regions can be increased.

A first investigative example is described. The diffusion depth of an implanted p-type dopant passing through a resist film of a SiC epitaxial layer (i.e., a p-type dopant punching-through a resist film) was verified. FIG. 17 is a diagram schematically depicting results of simulation of distribution of an implanted p-type dopant that passes through the resist film of the silicon carbide epitaxial layer. FIG. 17 depicts results of simulating the spreading of a p-type dopant when the p-type dopant, which passes through a resist film (resist mask) 202, is implanted in a SiC epitaxial layer (SiC substrate) 201 from a predetermined point (1 point) 203 at the surface (ion-implantation surface) of the resist film 202.

In FIG. 17, a horizontal axis indicates a depth [μm] of spreading of a p-type dopant 204 (hatched portion) from an ion-implantation surface (surface of the resist film 202), in the depth direction. In FIG. 17, a vertical axis indicates a length [μm] of spreading of the p-type dopant 204 from a predetermined point 203 (=0 [μm]) at the ion-implantation surface, in a direction parallel to the ion-implantation surface (lateral direction). As ion implantation conditions, aluminum (Al) is assumed to be the dopant and the acceleration energy is assumed to be 5 MeV. A thickness d1 of the resist film 202 is assumed to be 3.2 μm. The ion implantation, the resist film 202, and the SiC epitaxial layer 201 each correspond to the ion implantation process 62, the ion implantation mask 61, and the n-type epitaxial layer 23 in the first to third embodiments (refer to FIGS. 4, 5).

From the results depicted in FIG. 17, it was confirmed that, by a high acceleration energy of about 5 MeV, the implanted Al punched-through the resist film 202 and reached a depth d2 of 0.8 μm in the SiC epitaxial layer 201, from the surface of the SiC epitaxial layer 201. While not depicted, to completely prevent punch-through of the implanted Al through the resist film 202 by the high acceleration energy of about 5 MeV (i.e., blocking the implanted Al by the resist film 202), it was confirmed by the inventor that the thickness d1 of the resist film 202 has to be about 6 μm.

Thus, it was confirmed that by allowing a p-type dopant to punch-through the resist film 202, the thickness d1 of the resist film 202 can be reduced to about ½. In the first to third embodiments, it was confirmed that the acceleration energy for the ion implantation process 62 of a p-type dopant for forming the p-type column regions 42 and the thickness t1 of the ion implantation mask 61 (corresponds to the thickness d1 of the resist film 202) used in the ion implantation process 62 are suitably set, whereby the p-type dopant punch-through layer 3a of the predetermined thickness t2 and constituting the p-type base region 3 can be formed concurrently with the p-type column regions 42.

A second investigative example is described. A SJ-MOSFET (hereinafter, first example) fabricated by the described method of manufacturing the silicon carbide semiconductor device 70 according to the first embodiment (refer to FIG. 11) was verified with respect to the dopant concentration profile of the p-type column regions 42 in the depth direction. FIG. 18A is a characteristics diagram of results of simulation of a dopant concentration profile of an epitaxial layer of the first example in the depth direction. FIG. 18A depicts an n-type dopant concentration profile 211 and a p-type dopant concentration profile 212 along cutting line B-B′ in FIG. 18B.

In FIG. 18A, a horizontal axis indicates the depth from the front surface of the semiconductor substrate 20 (=0.0 μm) while a vertical axis indicates the dopant concentration. FIG. 18B is a cross-sectional view of the structure of the first example (corresponds to the perspective view depicted in FIG. 1). Cutting line B-B′ in FIG. 18B is along the sidewalls of the trenches 76 in the depth direction Z from the front surface of the semiconductor substrate 20 and passes the n⁺-type source regions 74, a p⁻-type base region 73a (in the p-type base region 73, portion thereof along the sidewalls of the trenches 76 where the p-type dopant concentration is lower), the n-type current spreading regions 72, and the p-type column regions 42.

Results of simulation of the dopant concentration profiles 211, 212 along cutting line B-B′ for the first example are depicted in FIG. 18A. Further, in FIG. 18A, the n-type dopant concentration profile 213 of the oblique ion implantations 84, 85 of an n-type dopant for forming the n-type current spreading regions 72 is indicated by a dashed line. In FIG. 18A, while the n-type dopant concentration profile 213 and portions due to the oblique ion implantations 84, 85 in the n-type dopant concentration profile 211 are depicted so as to not overlap, both are a same dopant concentration profile.

The n-type dopant concentration profile 211 includes, in the depth direction Z from the front surface of the semiconductor substrate 20, an n-type dopant concentration profile by the ion implantation 64 (refer to FIG. 7) for forming the n⁺-type source regions 74, an n-type dopant concentration profile by the oblique ion implantations 84, 85 (refer to FIG. 11) of an n-type dopant for forming the n-type current spreading regions 72, and an n-type dopant concentration profile of the n-type epitaxial layer 23, which are continuous with each other. The n-type dopant concentration profile 211 assumes the dopant to be nitrogen (N).

The p-type dopant concentration profile 212 is formed by the ion implantation process 62 (refer to FIGS. 3 and 4) for forming the p-type column regions 42 and includes, in the depth direction Z from the front surface of the semiconductor substrate 20, a p-type dopant concentration profile of the p-type dopant punch-through layer 3a and a p-type dopant concentration profile of the p-type column regions 42, which are continuous with each other. The p-type dopant concentration profile 212 assumes the dopant to be aluminum (Al). Diffusion of a p-type dopant in SiC is extremely small and the p-type dopant concentration profile 212 is maintained as is during the ion implantation process 62.

The p-type dopant concentration profile of the p-type column regions 42 is a box profile exhibited when the ion implantation process 62 for forming the p-type column regions 42 is assumed to be multistage ion implantation by an acceleration energy in a range from 60 keV to 8 MeV. In the multistage ion implantation (the ion implantation process 62), the dose of the ion implantation by the specified acceleration energy by which the range is near portions corresponding to the formation regions of the n-type current spreading regions 72 is reduced, whereby the p-type dopant concentration of the p-type column regions 42 in the portions corresponding to the formation regions of the n-type current spreading regions 72 can be relatively lower.

As depicted in FIG. 18A, it was confirmed that the p-type dopant concentration of the p-type column regions 42 at portions thereof of a depth corresponding to the n-type current spreading regions 72 is relatively lower, whereby even when the dose of the oblique ion implantations 84, 85 is reduced, the p-type column regions 42 are easily inverted to an n-type. Further, the dose of the oblique ion implantations 84, 85 is reduced, whereby the dose of the n-type dopant implanted in the p-type base region 73 by the oblique ion implantations 84, 85 is reduced thereby enabling adverse effects of the oblique ion implantations 84, 85 on channel mobility to be suppressed.

Further, as depicted in FIG. 18A, in the edge termination region 52 (refer to FIG. 3), portions 42b adjacent to the n-type current spreading regions 72 in the second direction Y and constituting surface layers of the p-type column regions 42, facing the n⁺-type source regions 74 have a relatively low Al concentration compared to portions 42c of the p-type column regions 42 closer to the n⁺-type drain region 1 than are the portions 42b. As a result, when the voltage withstanding structure 34 (the p-type regions 32, 33: refer to FIG. 3) is formed at the surface layers of the p-type column regions 42, the dopant concentration of the voltage withstanding structure 34 can be accurately controlled.

In the foregoing, the present disclosure is not limited to the embodiments described and various modifications within a range not departing from the spirit of the disclosure are possible. For example, the present disclosure is not limited to a MOSFET and is applicable to silicon carbide semiconductor devices having a structure that includes p-type regions that can be formed by a p-type dopant punch-through layer, between the front surface of the semiconductor substrate and the parallel pn layer, such as p-type base regions of an IGBT or p-type anode regions of a diode. Further, as the voltage withstanding structure, instead of the JTE structure, field limiting rings (FLRs), which are floating p-type regions, may be provided.

The silicon carbide semiconductor device and the method of manufacturing the silicon carbide semiconductor device according to the disclosure achieve an effect in that a silicon carbide semiconductor device that enables reduced costs can be provided.

As described, the silicon carbide semiconductor device and the method of manufacturing the silicon carbide semiconductor device according to the disclosure are useful for power semiconductor devices used in power converting equipment, power source devices of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
a semiconductor substrate made of silicon carbide, the semiconductor substrate having a first main surface and a second main surface opposite to each other;
a parallel pn layer provided in the semiconductor substrate, the parallel pn layer having a plurality of first-conductivity-type regions of a first conductivity type and a plurality of second-conductivity-type regions of a second conductivity type, repeatedly alternating each other in a first direction parallel to the first main surface of the semiconductor substrate;
a first semiconductor region of the second conductivity type, provided in the semiconductor substrate between the first main surface and the parallel pn layer;
a plurality of second semiconductor regions of the first conductivity type, each thereof selectively provided in the semiconductor substrate between the first main surface and the first semiconductor region;
a plurality of trenches penetrating through the plurality of second semiconductor regions, respectively, and through the first semiconductor region, in a depth direction of the silicon carbide semiconductor device and reaching the parallel pn layer;
a plurality of gate insulating films provided in the plurality of trenches;
a plurality of gate electrodes provided in the plurality of trenches via the plurality of gate insulating films;
a first electrode electrically connected to the first semiconductor region and the plurality of second semiconductor regions; and
a second electrode provided at the second main surface of the semiconductor substrate, wherein
each of the plurality of first-conductivity-type regions and the plurality of second-conductivity-type regions extends linearly in a second direction parallel to the first main surface and orthogonal to the first direction,
each of the plurality of trenches extends linearly parallel to the first main surface, and has at least a portion thereof facing one of the plurality of second-conductivity-type regions in the depth direction,
the first semiconductor region extends along sidewalls of the plurality of trenches, and
the first semiconductor region intersects with the plurality of second-conductivity-type regions at a plurality of intersecting portions.

2. The silicon carbide semiconductor device according to claim 1, wherein a dopant concentration of the plurality of intersecting portions is lower than a dopant concentration of the first semiconductor region.

3. The silicon carbide semiconductor device according to claim 1, wherein a depth of the plurality of second-conductivity-type regions is in a range of 0.8 μm to 3.2 μm.

4. A silicon carbide semiconductor device, comprising:
a semiconductor substrate made of silicon carbide, the semiconductor substrate having a first main surface and a second main surface opposite to each other;
a parallel pn layer provided in the semiconductor substrate, the parallel pn layer having a plurality of first-conductivity-type regions of a first conductivity type and a plurality of second-conductivity-type regions of a second conductivity type, repeatedly alternating with each other in a first direction parallel to the first main surface of the semiconductor substrate;
a first semiconductor region of the second conductivity type, provided in the semiconductor substrate between the first main surface and the parallel pn layer;
a plurality of second semiconductor regions of the first conductivity type, selectively provided in the semiconductor substrate between the first main surface and the first semiconductor region, and respectively corresponding to the plurality of first-conductivity-type regions and the plurality of second-conductivity-type regions;
a plurality of third semiconductor regions of the first conductivity type, respectively provided in the plurality of second-conductivity-type regions, at positions closer to the second main surface than is the first semiconductor region, and facing the plurality of second semiconductor regions in the depth direction;
a plurality of trenches penetrating through the plurality of second semiconductor regions, respectively, and through the first semiconductor region, in a depth direction of the silicon carbide semiconductor device and reaching the parallel pn layer;
a plurality of gate insulating films respectively provided in the plurality of trenches;
a plurality of gate electrodes provided in the plurality of trenches via the plurality of gate insulating films, respectively;
a first electrode electrically connected to the first semiconductor region and the plurality of second semiconductor regions; and
a second electrode provided at the second main surface of the semiconductor substrate, wherein
each of the plurality of first-conductivity-type regions and the plurality of second-conductivity-type regions extends linearly in a second direction parallel to the first main surface and orthogonal to the first direction,
each of the plurality of trenches extends linearly in the second direction and faces a corresponding one of the plurality of second-conductivity-type regions in the depth direction,
the plurality of second semiconductor regions is disposed apart from one another in the second direction, and respectively along sidewalls of the plurality of trenches, and
each of the plurality of third semiconductor regions has a first end and a second end opposite to each other in the first direction, the first end being in contact with a corresponding one of the plurality of gate insulating films at a corresponding sidewall of the plurality of trenches, and the second end being in contact with a corresponding one of the plurality of first-conductivity-type regions.

5. The silicon carbide semiconductor device according to claim 4, further comprising
a plurality of high-concentration regions of the second conductivity type, respectively provided between bottoms of the plurality of trenches and the plurality of second-conductivity-type regions, in contact with the plurality of second-conductivity-type regions, the plurality of high-concentration regions having a dopant concentration higher than a dopant concentration of the first semiconductor region.

6. The silicon carbide semiconductor device according to claim 4, wherein each of the plurality of second-conductivity-type regions has a portion thereof between adjacent two of the plurality of third semiconductor regions in the second direction, said portion having a dopant concentration lower than the rest of said each second-conductivity-type region.

7. A method of manufacturing a silicon carbide semiconductor device having
a semiconductor substrate made of silicon carbide, the semiconductor substrate having a first main surface and a second main surface opposite to each other; and
a parallel pn layer provided in the semiconductor substrate, the parallel pn layer having a plurality of first-conductivity-type regions of a first conductivity type and a plurality of second-conductivity-type regions of a second conductivity type, repeatedly alternating with each other in a first direction parallel to the first main surface of the semiconductor substrate,
the method of manufacturing comprising:
preparing a starting substrate made of silicon carbide, the starting substrate having a first surface and a second surface opposite to each other, the second surface constituting the second main surface of the semiconductor substrate;
as a first process, performing epitaxy at the first surface of the starting substrate, thereby forming a first-conductivity-type epitaxial layer of a first conductivity type, a surface of the first-conductivity-type epitaxial layer constituting the first main surface;
as a second process, forming, on the first-conductivity-type epitaxial layer, an ion implantation mask opened at portions corresponding to formation regions of the plurality of second-conductivity-type regions;
as a third process, performing ion-implantation of a dopant of the second conductivity type, using the ion implantation mask, thereby forming in the first-conductivity-type epitaxial layer, at openings of the ion implantation mask, the plurality of second-conductivity-type regions of a predetermined depth, and leaving portions of the first-conductivity-type epitaxial layer excluding the plurality of second-conductivity-type regions as the plurality of first-conductivity-type regions, to thereby form the parallel pn layer;
as a fourth process, forming a predetermined device structure between the first main surface and the parallel pn layer;
as a fifth process, forming a first electrode electrically connected to the device structure; and
as a sixth process, forming a second electrode at the second main surface, wherein
in the third process, the dopant of the second conductivity type is implanted by an acceleration energy, by which the dopant of the second conductivity type punches through the ion implantation mask and a range of the dopant of the second conductivity type corresponds to a surface region of the first-conductivity-type epitaxial layer, thereby forming a diffused second-conductivity-type layer in the surface region of the first-conductivity-type epitaxial layer by the dopant of the second conductivity type that has punched through the ion implantation mask, the diffused second-conductivity-type layer and the plurality of first-conductivity-type regions forming pn junctions through which a current passes, said current flowing in the device structure.

8. The method of manufacturing the silicon carbide semiconductor device, according to claim 7, wherein in the third process, a thickness of the diffused second-conductivity-type layer is 0.8 μm or more but not more than 1.5 μm.

9. The method of manufacturing the silicon carbide semiconductor device, according to claim 7, wherein
in the second process, a thickness of the ion implantation mask is not more than 6 μm, and
in the third process, the acceleration energy of the ion implantation is 1 MeV or more but not more than 8 MeV.

10. The method of manufacturing the silicon carbide semiconductor device, according to claim 7, wherein
the device structure includes:
the parallel pn layer;
a first semiconductor region of the second conductivity type, provided between the first main surface and the parallel pn layer;
a plurality of second semiconductor regions of the first conductivity type, each selectively provided between the first main surface and the first semiconductor region;
a plurality of trenches penetrating through the plurality of second semiconductor regions and the first semiconductor region in the depth direction and reaching the parallel pn layer;
a plurality of gate insulating films provided in the plurality of trenches; and
a plurality of gate electrodes provided in the plurality of trenches via the plurality of gate insulating films, wherein
the fourth process includes
as a seventh process, selectively forming the plurality of second semiconductor regions in surface regions of the diffused second-conductivity-type layer and leaving a portion of the diffused second-conductivity-type layer excluding the plurality of second semiconductor regions, as the first semiconductor region;
as an eighth process, forming the plurality of trenches that penetrate through the plurality of second semiconductor regions and the first semiconductor region in the depth direction and reach the parallel pn layer; and
as a ninth process, forming the plurality of gate electrodes on the plurality of gate insulating films, in the plurality of trenches.

11. The method of manufacturing the silicon carbide semiconductor device, according to claim 10, wherein
in the third process, the plurality of second-conductivity-type regions are formed each extending linearly in a second direction that is parallel the first main surface and orthogonal to the first direction,
in the eighth process, the plurality of trenches are formed respectively penetrating through the plurality of second semiconductor regions and the first semiconductor region in the depth direction and reaching the plurality of second-conductivity-type regions, and each extending linearly in the second direction,
in the seventh process, the plurality of second semiconductor regions is formed apart from one another in the second direction, respectively along sidewalls of the plurality of trenches, and
the method of manufacturing further includes, before the ninth process, ion-implanting a dopant of the first conductivity type into the sidewalls of the plurality of trenches from a direction oblique to the first main surface and thereby forming in the plurality of second-conductivity-type regions, at positions facing the plurality of second semiconductor regions in the depth direction and closer to the second main surface than is the first semiconductor region, a plurality of third semiconductor regions of the first conductivity type, penetrating through the plurality of second-conductivity-type regions in the first direction and being in contact with the plurality of first-conductivity-type regions, respectively.
